(19) United States
(12) Patent Application Publication
(10) Pub. No.: US 2024/0304878 A1
(43) Pub. Date: Sep. 12, 2024

(54) LITHIUM METAL BATTERY PROGNOSTIC OF IMPENDING CAPACITY FAILURE

(71) Applicant: GM GLOBAL TECHNOLOGY OPERATIONS LLC, Detroit, MI (US)

(72) Inventors: Charles W. Wampler, Birmingham, MI (US); Meinan He, Birmingham, MI (US); Meng Jiang, Rochester Hills, MI (US); Yongjie Zhu, Troy, MI (US); Chunhao J. Lee, Troy, MI (US)

(73) Assignee: GM GLOBAL TECHNOLOGY OPERATIONS LLC, Detroit, MI (US)

(21) Appl. No.: 18/179,722

(22) Filed: Mar. 7, 2023

(51) Int. Cl. H01M 10/48; G01R 31/3842; G01R 31/389; G01R 31/392

(52) U.S. Cl. CPC H01M 10/482; G01R 31/3842; G01R 31/389; G01R 31/392; H01M 10/488; H01M 10/052

(57) ABSTRACT

Catastrophic capacity failure in Lithium Metal Battery (LMB) cells is preceded by an increase in battery resistance. At a fixed temperature, the onset of failure occurs at the same value of resistance across the cell(s). Various embodiments use this phenomenon as a prognostic for predicting when such a failure is likely to occur. In various aspects, a normalized resistance in a vehicle or other device may be detected and compensated for temperature differences. The compensated resistances, a threshold state of charge (SOC), and capacity differences may be used to predict capacity failure in remaining capacity or distance (e.g., miles), to identify failing LMB cells, and to send a prognostic alert.

### INTRODUCTION

Catastrophic capacity failure of lithium metal batteries (LMBs) may cause difficulties for battery management due to its unpredictable characteristics. The problem is exacerbated in the case where the LMB battery cells are implemented in an electric vehicle (EV), in which a sudden failure of one or more LMB battery cells may render the EV inoperable, potentially leaving the driver stranded on an active roadway or facing a similar predicament. For LMB cells implemented in whatever electrical system, no prognostic is presently available to warn a consumer in advance.

### SUMMARY

In an aspect of the present disclosure, an electrical system includes a battery pack including a plurality of Lithium Metal Battery (LMB) cells. Each LMB cell of the plurality has a respective terminal pair. The electrical system further includes a processing system coupled to the respective terminals pairs. The processing system is configured to detect, during LMB cell operation, increasing values of a normalized resistance across at least one of the terminal pairs corresponding to an identified at least one of the LMB cells. The processing system is further configured to predict, based on the increasing values of normalized resistance, a throughput capacity corresponding to an anticipated failure of the identified at least one of the LMB cells. The processing system is also configured to provide a prognostic alert based on the prediction.

In various embodiments, the anticipated failure of the identified at least one of the LMB cells corresponds to the increasing values of normalized resistance crossing a threshold at a preselected state of charge (SOC). In various embodiments, the processing system is configured to detect the normalized resistance (R^{norm}) such that
R^{norm}=R₀Qₜₒₜ is in units of voltage (V)/C-rate,
C-rate is current divided by total capacity, current/Qₜₒₜ,
Qₜₒₜ represents a total capacity of the at least one of the LMB cells,
R₀ represents a resistance across the at least one of the LMB cells.

In various embodiments, the processing system further includes a voltage sensor configured to measure the voltage (V) across the at least one of the terminal pairs, and a current sensor configured to measure the current (I) across the at least one of the LMB cells. The processing system may further be configured to periodically estimate the total capacity Qₜₒₜ of the at least one of the LMB cells and to obtain the values of normalized resistance (R^{norm}) using the estimated Qₜₒₜ values and one or both of the measured voltage (V) or the measured current (I). In some embodiments, the processing system is configured to convert the values of normalized resistance (R^{norm}) to temperature-compensated resistance (R^{comp}) and to assess accuracies of values of R^{comp} based at least in part on the deviation of temperatures from a reference temperature. The processing system may further be configured to predict the anticipated failure by monitoring a trend line fit to the values of the temperature compensated resistance (R^{comp}) and a throughput capacity Q over a plurality of measurements. The processing system may also be configured to identify an accelerated rate of increase of the values of the normalized resistance as an indicator of imminent capacity failure of the identified at least one of the LMB cells.

In another aspect of the present disclosure, a vehicle includes a vehicle body. A battery pack is arranged within the vehicle body. The battery pack includes a plurality of Lithium Metal Battery (LMB) cells. Each LMB cell has a cathode and a lithium anode that together constitute a terminal pair of the respective LMB cell. The vehicle further includes a processing system coupled to the respective terminals pairs. The processing system is configured to detect, over a period of time, progressively increasing values of a normalized resistance between terminal pairs corresponding to at least one identified LMB cell of the plurality. The processing system is configured to predict a remaining throughput capacity prior to imminent failure of the at least one identified LMB cell wherein the increasing values cross a threshold at a reference state of charge (SOC). The processing system is configured to provide a prognostic alert based on the prediction.

In various embodiments, the processing system of the vehicle includes voltage and current sensors for respectively measuring voltage (V) across the terminal pairs and current flow (I) through the LMB cells. The processing system may further include battery state estimation (BSE) logic to monitor cell capacities, Qₜₒₜ_{ⱼ}. The variable j denotes an index over the plurality of LMB cells, and the SOC of the battery pack. The processing system may further include a memory coupled to the voltage and current sensors for storing data.

In various embodiments, the processing system may detect the progressively increasing values at least in part by reading, from the memory, stored values of an open-circuit voltage (OCV) of the at least one identified LMB cell. The OCV is measured at different SOC values during a near-zero C-rate cycle prior to vehicle operation. The processing system may measure, over the period of time, a plurality of first sets of V values. Each V value in each first set may represent a voltage measured at a throughput capacity (Q). The processing system may further be configured to detect, at the selected SOC value, and based in part on a difference between the stored OCV values and the measured V values in each set, the normalized resistance.

In various embodiments, the processing system is further configured to measure, over the time period, a plurality of values of the normalized resistance values (R^{norm}), throughput capacity (Qᵢ) and temperatures (Tᵢ) of the at least one identified LMB cell when the SOC crosses a target value. The processing system may determine a first accuracy of each of the R^{norm} measurements including modifying or deleting unreliable measurements. The processing system may store the R^{norm}, Q and T values in the memory as an i-th measurement point in a sequence of such points. The processing system may also perform temperature compensation for selected R^{norm} values to obtain a temperature-compensated resistance (R^{comp}) to store in the memory with the corresponding Q and T values. The processing system may be configured to determine a second accuracy of R^{comp} for each new point including R^{comp}, Q and T values including assigning a different weight to one or more of the R^{comp} values based on a measured temperature deviating from a reference temperature and deleting the R^{comp}ᵢ values that are based on measurements that exceed a threshold age.

In various embodiments, the processing system is configured to fit a trend line or curve in a plot of R^{comp} versus Q over the period of time. The trend line or curve may have an intercept and a slope m*. The processing system may further be configured to predict a value (Q*) of the battery capacity wherein R^{comp} crosses an onset resistance. In various embodiments, to predict a remaining capacity of the at least one identified LMB cell, the processing system is configured to determine, for each of the plurality of LMB cells, a difference between the value (Q*) of the battery throughput capacity wherein the trend line of R^{comp} crosses the onset resistance, and the present battery throughput capacity (Q).

The processing system may further be configured to predict a remaining throughput capacity of the at least one identified LMB cell using a slope of the trend line or curve. The processing system may also be configured to determine a predicted distance (e.g., number of miles or kilometers) to failure for inclusion within the prognostic alert. The processing system may further be configured to convey the prognostic alert to one or both of an output display in the vehicle or to a remote location via a wireless network. The prognostic alert may further include an identification of the at least one LMB cell corresponding to the anticipated failure.

In still another embodiment, a vehicle includes a vehicle body. A battery pack is arranged within the vehicle body and includes a plurality of batteries connected in series. Each battery includes at least one lithium metal battery (LMB) cell having a cathode and a lithium anode that together constitute a pair of terminals of the at least one LMB cell. A processing system is coupled to the plurality of LMB cells. The processing system is configured to measure a current through the plurality of LMB cells over time to establish a throughput capacity (Q) of the battery pack. The processing system tracks a state of charge (SOC) of the battery pack over time. When the SOC crosses a reference SOC, the processing system is configured to detect a normalized resistance (R^{norm}) across the terminals of the at least one LMB cell and assess a detection accuracy. The processing system stores values of R^{norm}ᵢ, throughput capacity Qᵢ, and a measured temperature (Tᵢ) at the ith measurement in a memory. The processing system converts R^{norm}ᵢ to a temperature-compensated resistance R^{comp}ᵢ and reassesses an accuracy of values of (R^{comp}ᵢ) based on deviations from a reference temperature. The processing system fits a trend line or curve to points (Qᵢ, R^{comp}ᵢ). The processing system also predicts a capacity (Q*) at which the trend line or curve of R^{comp}ᵢ will cross an onset resistance. The processing system estimates a capacity to failure (Q*−Q) of the at least one LMB cell based on the trend line or curve and provides a prognostic alert on a vehicle display.

In various embodiments, the compensated resistance (R^{comp}ᵢ) is obtained using an Arrhenius relationship. The processing system may further be configured to predict the capacity to failure by determining when the trend line of the compensated resistance R^{comp}ᵢ crosses a specified threshold. The processing system may also provide the prognostic alert when a minimum capacity change (ΔQₘᵢₙ) falls below a first threshold or a maximum slope of the trend line crosses a second threshold, where for each of the plurality of LMB cells, ΔQ=Q*−Q, and ΔQₘᵢₙ is a smallest value of the plurality of LMB cells.

The above summary is not intended to represent every embodiment or every aspect of the present disclosure. Rather, the foregoing summary merely provides non-exhaustive examples of some of the novel concepts and features set forth herein. The above features and advantages, and other features and attendant advantages of this disclosure, will be readily apparent from the following detailed description of illustrated examples and representative modes for carrying out the present disclosure when taken in connection with the accompanying drawings and the appended claims. Moreover, this disclosure expressly includes the various combinations and sub-combinations of the elements and features presented above and below.

### BRIEF DESCRIPTION OF THE DRAWINGS

The accompanying drawings, which are incorporated into and constitute a part of this specification, illustrate implementations of the disclosure and together with the description, explain the principles of the disclosure.

FIG. 1 is a schematic illustration of an example electrical system having a battery pack and a processing system, with the latter including battery state estimation (BSE) logic configured to regress battery parameters and estimate a state of the battery pack, e.g., state of charge (SOC), using an empirical model.

FIG. 2 is a schematic illustration of an example battery cell whose state may be estimated in real time according to the present strategy.

FIG. 3 is a schematic logic flow diagram illustrating further aspects of the battery and processing system of FIG. 1 according to some embodiments.

FIG. 4 is a graphical representation of curves of LMB cell voltage (volts) versus battery capacity Q (milliamp-hours) across a plurality of charge-discharge cycles when charging and discharging the LMB cells quickly, during regular electric vehicle (EV) operation.

FIG. 5 is a graphical representation of an open-circuit voltage (OCV) in volts as a function of state of charge (SOC) (measured from 0 to 1 or equivalently, 0% to 100%), measured during LMB cell manufacturing with a near-zero (slow relative to active operation) charge-discharge rate.

FIG. 6 is a graphical representation of a normalized resistance R(x, Q_{TOTi}) (in V/C-rate or Volt-hours) versus SOC (x) across a plurality of different charge-discharge cycles.

FIG. 7 is a graphical representation of three example LMB cells reaching catastrophic capacity failure between 300 and 400 charge-discharge cycles, and more specifically, values of constant current discharge capacity Q^{D}_{CC} and constant current charge capacity Q^{C}_{CC} (in milliamp-hours (mAh)) at increasing charge-discharge cycles.

FIG. 8A is a graphical representation of failure onset of the first cell 1 in FIG. 7, and more specifically, curves showing, at different charge-discharge cycles, values of normalized resistance R^{norm} (in Volt-hours (V-h)) as a function of SOC x and Q_{TOT} versus SOC x.

FIG. 8B is a graphical representation of failure onset of the second cell 2 in FIG. 7, and more specifically, curves showing, at different charge-discharge cycles, values of normalized resistance R^{norm} as a function of SOC x and Q_{TOT} versus SOC x.

FIG. 9 is a graphical representation of LMB cell capacity and normalized resistance of three LMB cells including total capacity (Q_{TOT}) and constant current capacity (Q_{CC}) in milliamp-hours (mA-h), and normalized resistance (V/C-rate) in volt-hours (Vh) at SOC=0.5 or 50%.

FIG. 10 is a flow diagram illustrating an exemplary method for predicting a remaining battery capacity or mileage to anticipated failure in an EV and for providing a prognostic alert.

FIG. 11 is a flow diagram illustrating another exemplary method for predicting battery failure in advance in a vehicle using a normalized resistance and for providing a prognostic alert to the driver.

The appended drawings are not necessarily to scale and may present a simplified representation of various features of the present disclosure as disclosed herein, including, for example, specific dimensions, orientations, locations, and shapes. In some cases, well-recognized features in certain drawings may be omitted to avoid unduly obscuring the concepts of the disclosure. Details associated with such features may be determined in part by the particular intended application and use environment.

### DETAILED DESCRIPTION

The present disclosure is susceptible of embodiment in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” For example, “optimal measurements” may include one or more optimal measurements. Moreover, words of approximation such as “about,” “almost,” “substantially,” “generally,” “approximately,” etc., may be used herein in the sense of “at, near, or nearly at,” or “within 0-5% of”, or “within acceptable manufacturing tolerances”, or logical combinations thereof. As used herein, a component that is “configured to” perform a specified function is capable of performing the specified function without alteration, rather than merely having potential to perform the specified function after further modification. In other words, the described hardware, when expressly configured to perform the specified function, is specifically selected, created, implemented, utilized, programmed, and/or designed for the purpose of performing the specified function.

As noted, imminent failure of LMB cells may cause chaos in battery management, possibly resulting in a stranded driver and an inability to address the problem prior to all-out catastrophic battery failure. The inventors have confirmed that catastrophic capacity failure in LMB cells/cell groups/batteries is preceded by an increase in battery resistance, e.g., as measured across the terminals of a cell or an LMB cell group. Aspects of the present disclosure capitalize on this phenomenon as an in-vehicle prognostic for predicting how far into the future such a failure is likely to occur. In various embodiments, different techniques are described for estimating resistance. However, other such techniques may be used and remain within the scope of the disclosure. While the specific examples are given in the context of a vehicle, the disclosure may be extended to different LMB cell implementation and is especially useful when implemented in forms of transportation. However, the aspects herein may likewise be useful in alternative embodiments in which the LMB cells are arranged in a mobile robot or mobile machine tool, for example. In these latter cases where efficiency may be critical to the value of a manufacturer, a prognostic indicating pending failure of the battery may provide the manufacturer with the time it needs to substitute the failing robot/tool with another operational one, allowing the manufacturer to maintain optimal capacity on the manufacturing floor of whatever component or machine is being manufactured, while concurrently servicing the failing machine used with LMB batteries for cell repair or replacement.

In addition, further aspects of the disclosure describe systems and methods for normalizing the resistance and compensating the normalized resistance to account for temperature. These techniques may dramatically increase the accuracy of “capacity to failure” or “miles/kilometers to failure” for the failing cell(s). In the context of a vehicle, after detecting the relevant resistance values and predicting the failure of an identified cell as discussed in detail below, this information along with the identity of the failing cell or battery portion may be communicated to the driver as an alert including prognostic data over an output display screen, for example, one or more alert lights, and in some examples, a prognostic report transmitted to a remote location such as a service center over a proprietary network to enable the driver to receive further information and recommendations on service.

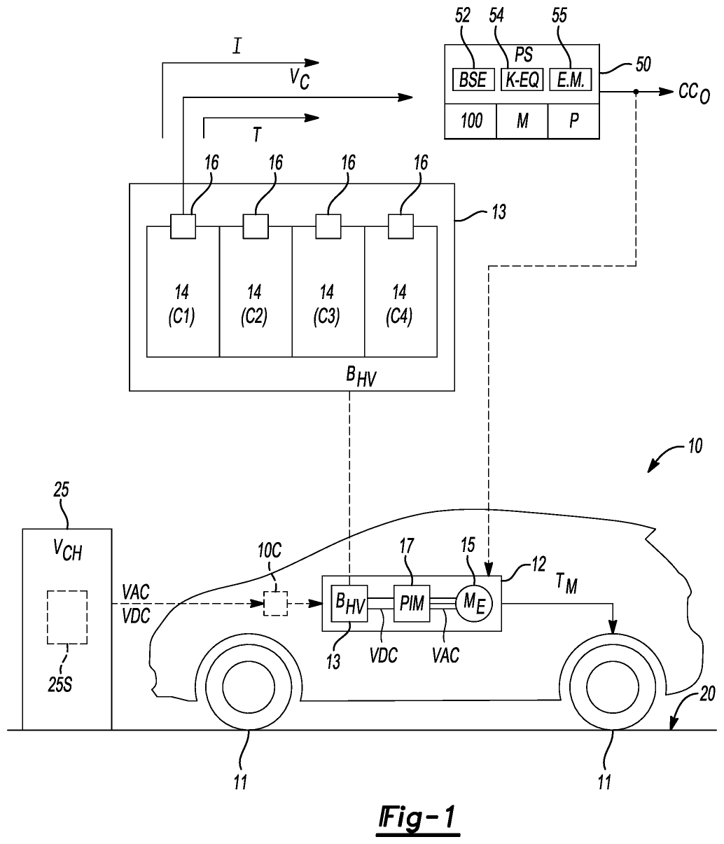

Referring to the drawings, wherein like reference numbers refer to like components, FIG. 1 depicts an exemplary vehicle 10 having an onboard electrical system 12, a processing system (PS) 50, and a set of road wheels 11, with the latter being in rolling contact with a road surface 20. The vehicle 10 is illustrative of just one possible application of the present teachings and is used herein solely for the purpose of illustrative consistency. Those of ordinary skill in the art will appreciate that the present teachings may be extended to a wide variety of dynamic systems and devices including but not limited to motor vehicles, watercraft, aircraft, rail vehicles, mobile platforms, robots, machine tools, 3-D printers, powerplants, or other systems having an electrical system 12. In fact, the principles of the disclosure may be broadly applied to devices that use LMBs as a power source, including without limitation power tools, cell phones, tablets, laptop or notebook computers, etc., provided the device has, or is later equipped with, a computational resource to record the measurements.

The electrical system 12 in the non-limiting embodiment of FIG. 1 includes a high-energy/high-voltage multi-cell battery pack 13 (B_{HV}) whose various battery parameters and states are estimated by the processing system 50 as described by the principles herein. By way of example and not limitation, the battery pack 13 may have a lithium-ion battery chemistry and may be capable of outputting at least 18V and as much as 400V or more depending on the configuration. In various embodiments, the multi-cell battery pack 13 includes a plurality of Lithium Metal Battery (LMB) cells. LMB cells are battery cells that have metallic lithium as the anode material. LMB batteries stand apart from other types of lithium-ion batteries due to their high energy density. Rechargeable LMB cells such as the ones in the disclosed embodiments may have cathode material that varies with the implementation. They may include, for example, NMC (including lithium, nickel, manganese, cobalt, and oxygen); LMO (including lithium, manganese, and oxygen), LFP (lithium iron, phosphoric acid, and oxygen), LCO (lithium, cobalt, and oxygen), among other possible materials.

In some embodiments of the vehicle 10, the electrical system 12 includes a polyphase rotary electric machine (M_{E}) 15 such as a motor-generator unit. In such an embodiment, motor torque (arrow T_{M}) from the energized electric machine 15 may be transmitted to one or more of the road wheels 11 and/or to another coupled load. A power inverter module (PIM) 17 is disposed between the battery pack 13 and the electric machine 15 and configured, in response to pulse width modulation or other suitable high-speed switching control signals and operation of phase-associated semiconductor switches (not shown), to invert a direct current (DC) voltage (“VDC”) from the battery pack 13 and thereby generate a polyphase/alternating current (AC) voltage (“VAC”) for energizing stator windings (not shown) of the electric machine 15. Likewise, operation of the PIM 17 may convert an AC voltage (VAC) from the electric machine 15 into a DC voltage (VDC) suitable for recharging the battery pack 13.

The battery pack 13 noted generally above includes a plurality of LMB battery cells 14. Four such battery cells 14 are individually labeled C1, C2, C3, and C4 in FIG. 1 for added clarity and simplicity. The actual number of battery cells 14 used in the construction of the battery pack 13 is application-specific and depends on the energy requirement of electrical loads or devices powered by the battery pack 13, such as but not limited to the rotary electric machine 15. Although shown schematically for illustrative simplicity and clarity, the electric machine 15 may be coupled to the road wheels 11 directly or via intervening gear arrangements and drive axles to power the electric machine 15 in its capacity as an electric traction motor and thereby propel the vehicle along a road surface 20.

Powerflow to or from the electrical system 12 may be managed in real-time by the processing system 50, e.g., when configured as a battery system manager or another control device or devices, with the processing system 50 regulating ongoing operation of the electrical system 12 via output control signals (arrow CCo). In some embodiments, the battery management system including processing system 50 may be part of the electrical system. According to the present strategy, the processing system 50 employs battery state estimation (BSE) logic 52, an application-specific equivalent circuit model (K-EQ) 54, and sensors 16 that collectively measure and communicate input signals to the processing system 50 and its resident BSE logic 52. Such input signals in the illustrated configuration include cell voltages (arrow V_{C}), battery current (arrow I), and battery temperature (arrow T). The input signals may be determined locally within each battery cell 14 or measured collectively at the level of the battery pack 13 and back calculated or estimated from such levels in different embodiments. For purposes of this disclosure, sensors 16 are considered to be part of the processing system, even though the sensors 16 may be physically located at least in part at or proximate the LMB cells 14 or cell groups. As an example, a temperature sensor 16 may send digital or analog values, or a waveform, representing the temperature of an LMB cell. The analog value or waveform may be digitized at the analog front end of the processing system 50, converted to digital values, and provided to one or more processors P for further analyses. Similarly, the capacity throughput measurements may involve voltage and/or current measurements from respective sensors 16, which may in turn be deemed part of the processing system 50 for purposes of the embodiments herein.

The processing system 50, which may be configured as part of a larger battery management system or as a separate computer device or network of such devices, includes one or more processors (P), e.g., a microprocessor or central processing unit (CPU) (or a plurality of such microprocessors or CPUs, a processor having one or more pipelines and multiple cores for executing multiple threads), memory (M) in the form of read only memory (ROM), random access memory (RAM), such as dynamic RAM (DRAM), electrically-programmable read only memory, etc., a high-speed clock for providing or recovering clock signals when sending or receiving data, respectively, analog-to-digital and digital-to-analog circuitry, input/output circuitry and devices, a memory processing system, a high-speed bus for fast data transfer, a transceiver for sending and receiving wireless signals over one or more cellular or private networks to or from another location, and appropriate signal conditioning and buffering circuitry. The strategies described below may be encoded as machine-readable instructions collectively that, when executed by the processing system 50 or processor(s) P, may enable the processing system 50 or processor(s) P to perform one more of the core functions as described below.

The processing system 50 may have, as part of its designated control functionality, the tasks of monitoring and controlling temperature, state of charge, voltage, and other performance characteristics of the battery pack 13.

It will be appreciated that the terms “processing system,” “processor,” and “microprocessor” for purposes of this disclosure may, but need not, be limited to a single processor or integrated circuit. Rather, they may encompass plural or multiple processors in a single configuration and/or a variety of different physical circuit configurations. Non-exhaustive examples of the term “processor” include (1) one or more processors, located in a vehicle for vehicular implementations (including without limitation an electronic control unit (ECU)), or located in another device with LMB cells, such that the one or more processors collectively perform the set of functions described below and that interface with other components as governed by the relevant design specifications of the sensors_pack (in the case of a vehicle) and other components, and (2) processors of potentially different types, including reduced instruction set computer (RISC)-based processors, complex instruction-set computer (CISC)-based processors, multi-core processors, dedicated hardware processors (e.g., digital signal processors), and the like.

The processing system 50 may further include memory M (e.g., dynamic or static random access memory (e.g., “DRAM” or “SRAM”)) as described below. While the embodiment of FIG. 1 is such that processing system 50 is construed to include the sensors that interface with the LMB cells/groups, in other implementations the different modules may be partitioned in a different manner without departing from the scope and spirit of the present disclosure. For example, the processing system 50 may include solid state drives, magnetic disk drives and other hard drives. The processing system 50 may also incorporate flash memory including NAND memory, NOR memory and other types of available memory. The processing system 50 may also include read only memory (ROM), programmable ROM, electrically erasable ROM (EEROM), electrically erasable programmable ROM (EEPROM) and other available types of ROM. The processing system 50 and the operating system and other applications relevant to the battery failure predictions may include updateable code or firmware, e.g., updated wirelessly via a network or otherwise. As noted, the memory (e.g., M) in the processing system 50 may further include one or more cache memories, which may also be integrated into one or more individual processors/central processing units (CPUs) as L1 caches. The caches may be embedded within the processor, or they may be discrete devices, or some combination thereof. In some embodiments, L2 and L3 cache memories may exist as well.

In executing the present method 100, the processing system 50 automatically derives the battery's present operating state, including a bulk state of charge (SOC) and state of power (SOP) of the battery pack 13. The processing system 50 may do so using the BSE logic 52 with the assistance of the equivalent circuit model K-EQ 54 for emulating various circuit-specific values and conditions, like current, charge throughput, process corners, temperatures and for modeling behavior of the battery pack 13 using, as circuit elements, the battery voltage, a hysteresis voltage source, ohmic resistance, battery and/or cell voltage, resistance, and capacitance, etc. The equivalent circuit model may also account for factors such as surface charge on the various battery cells 14. Depending on the complexity of the equivalent circuit model (K-EQ) 54, the equivalent circuit model 54 may also account for solid-state diffusion voltage effects and other higher and/or lower frequency voltage effects occurring within the constituent battery cell(s) 14 of the battery pack 13. Collectively, the various voltage effects are added or subtracted from the open-circuit voltage of the battery cell(s) 14.

The specific configuration of the equivalent circuit model 54 is based on the particular application and construction of the battery pack 13 and thus may have a wide variety of constructions. Non-limiting representative example constructions usable as the equivalent circuit model 54 may be found, for instance, in U.S. Pat. No. 9,575,128 entitled “Battery State-Of-Charge Estimation For Hybrid and Electric Vehicles Using Extended Kalman Filter Techniques” issued to the present Assignee on Feb. 21, 2017, U.S. Pat. No. 6,639,385 entitled “State of Charge Method and Apparatus” issued to the present Assignee on Oct. 28, 2003, and U.S. Pat. No. 7,324,902 entitled “Method and Apparatus for Generalized Recursive Least-Squares Process for Battery State of Charge and State of Health” issued to the present Assignee on Jan. 29, 2008, the contents of each of which are hereby incorporated by reference in their entireties as if fully set forth herein.

State of charge and state of power estimations may be adapted in real-time using the BSE logic 52. In an embodiment, the BSE logic 52 may include an extended Kalman filter and an additional empirical model 55 (E.M.), which may include logic circuits or executable code or a combination thereof, to improve overall estimation accuracy in the face of a constant baseline current flowing into or out of the battery pack 13 of FIG. 1. As will be appreciated by those of ordinary skill in the art, an extended Kalman filter formulation is typically used to treat system models having the following general form:

$${x}_{k + 1} = f ( {x}_{k} , {u}_{k} ) + {w}_{k}$$

$${z}_{k} = h ( {x}_{k} ) + {n}_{k}$$

where wₖ and nₖ are noise factors. For the representative BSE logic 52 of the present disclosure, the input is uₖ−iₖ=current to or from the battery pack 13. The measured value is zₖ=Vₖ, which in this instance is the cell voltage of a battery cell 14 or a pack voltage of the battery pack 13 shown schematically in FIG. 1. xₖ is the state vector including battery parameters to be estimated by the BSE logic 52.

Aspects of the present disclosure use a resistance of the LMB cell(s), which is normalized. Various techniques for detecting this resistance are discussed but are not exhaustive. As understood in the art, the estimated state of the battery pack 13 and other deterministic systems is the smallest vector summarizing the system's collective past. Alternatives to the extended Kalman filter formulation within the scope of the disclosure include but are not limited to Sigma-Point Kalman Filters and the like, as well as formulations that do not follow Kalman filter formalism, e.g., recursive least-squares regression, particle filters, etc. The extended Kalman filter, which effectively uses a single point and partial derivatives of the associated equivalent circuit model 54, is therefore just one possible approach to regressing battery parameters within the scope of the disclosure and determining a number of relevant parameters as described below.

Still referring to FIG. 1, the present solution enabled by the processing system 50 and its resident BSE logic 52 are intended to operate in electrical systems ordinarily having a constant baseline current, such as the exemplary electrical system 12 and battery pack 13. The baseline current contemplated herein may be a charging current supplied by an offboard charging station (V_{CH}) 25 that is connectable to the vehicle 10, e.g., via a charging port 10C, to initiate a charging cycle of the battery pack 13. The charging station 25 may deliver an AC or DC charging current depending on the configuration of the offboard charging station 25, or the baseline current may be a battery current supplied by the battery pack 13 to power the electric machine 15, a resistive element, and/or another electrical load. In some embodiments the charging station 25 may be adapted for use as a smart charger 25S, and thus equipped with associated processors, logic, sensors, and other requisite hardware and software for communicating with the processing system 50 to determine the charging requirements of the battery pack 13.

As part of a computer-executable method 100 for estimating the state of the battery 13, the processing system 50 may receive the individual currents (Ic) from the sensors 16, with the voltages (V_{C}) likewise measured or modeled. In executing the method 100, the processing system 50 automatically derives the battery's present state, including a predicted total voltage and, from there, a bulk state of charge (SOC) and a state of power (SOP) of the battery pack 13. The SOC is a measure of the ratio of the available capacity of an LMB-battery in a battery pack to the maximum possible charge that may be stored in a battery. In some configurations the processing system 50 may perform one or more of these measurements with the assistance of an empirical model 55 capturing higher-frequency transient voltage effects occurring within the battery cell(s) 14, which may be added or subtracted from the open-circuit voltage of the battery cell(s) 14. SOC estimation may be adapted in real-time, e.g., using a Kalman filter or variant as set forth below, to improve the accuracy of the empirical model 55 and the estimated voltages.

In particular, the processing system 50 is configured, using the empirical model 55, to estimate the cell voltage, SOC, and SOP of the various battery cells 14 with a high level of accuracy relative to bulk or discrete approaches such as RC-pair modeling. The empirical model 55 may be used to model higher-frequency transient behavior and effects and passes the actual state signals from the sensors 16 through a bank of low-pass and high-pass filters having respective time-constants collectively spread over a predefined range of interest. At least some of the low-pass filters may be embodied as band-pass filters within the scope of the disclosure.

As used herein, the term “constant” with respect to the baseline current refers to an electrical current having very low frequency content, e.g., less than about 0.01 Hz or less than about 0.005 Hz in different embodiments. The term “very low” is to be understood relative to the sampling speed of the processing system 50 when implementing the BSE logic 52. Such sampling speed may be less than about 1-10 Hz in an exemplary embodiment. As the offboard charging station 25 may be optionally embodied as a DC fast-charger capable of rapidly charging the battery pack 13 with a DC charging voltage and associated DC charging current, a DC current waveform epitomizes constancy within the scope of present disclosure, and thus the constant baseline current treated herein may be a DC charging current or an alternating current (AC) charging current having the above-defined very low frequency content.

As noted above, the processing system 50 of FIG. 1 is configured for estimating battery parameters and a present state of a battery pack 13 using the BSE logic 52. As appropriate in the context, battery pack 13 may also be referred to herein as battery 13. In an embodiment, the method 100 includes receiving or delivering a constant baseline current via the battery 13 from or to a load, respectively for purposes of obtaining certain measurements germane to the embodiments described herein. With respect to the current control logic of empirical model 55, a baseline current and the current oscillations may sum to combine and form a final current. Various exemplary embodiments model current oscillations as a Pseudo-Random Binary Signal or PRBS oscillation. Alternative embodiments of the current oscillations exist, including a frequency-varied signal such as a pulse-width modulation or pulse-density modulation signal, a sequence of chirp signals, or other varied frequency signals configured to generate sufficient excitation to the BSE logic 52. While the frequency of the current oscillations may vary with the application or within a given implementation, the frequency content should be high relative to the constant baseline current, e.g., a range of about 0.1-1 Hz, or anywhere in such a range, e.g., discrete frequencies of 0.1 Hz, 0.5 Hz, or 1 Hz.

According to the present method 100, a battery parameter of the battery pack 13 such as regressed R-ohmic, capacitance, or OCV may be automatically estimated via the BSE logic 52 of FIG. 1 concurrently with injection of the current oscillations, with “injection” as used herein referring to a summed combination or overlay of the current oscillations (i_{OSC}), respectively with or onto a constant baseline current as indicated by a summation node (+). Temporarily, the resultant waveform, i.e., the final current, is provided to or by the battery pack 13. The processing system 50 of FIG. 1 may then estimate the present state of the battery pack 13 using the estimated battery parameter.

Referring still to FIG. 1, the principles of the present disclosure are applicable to a broad range of physical configurations of the battery pack 13. In some configurations, for example, the LMB battery cells 14 are organized as a plurality of such cells arranged in a group. The respective anodes of each cell in a group may be coupled together, and the respective cathodes in the group may be also coupled to the other cathodes. The groups may thereupon be electrically serially connected. Thus, the cell group may also be accessed by the processing system 50 or the sensors 16 as a string of groups connected in serial. In this configuration, the processing system 50 accesses a potential difference across a cell group by probing the corresponding anode and cathode of that group. Using a current sensor 16, the processing system 50 may also access a single current across the plurality of serial battery groups. It will be appreciated by those skilled in the art that in other embodiments, the battery pack may be configured as a single cell, in which case measurement information is attributable to the cell (and potentially other conductors used by the cell), or a cell group. In still other embodiments, the battery pack may encase multiple serial strings of LMB cells or LMB cell groups. Simpler configurations may be realized in connection with simpler applications, such as the use of single battery cells or small groups thereof in an electrical system which lacks the sophistication and electrical power needed in an EV. The processing systems 50 may be scaled to the correct size and number of circuit elements to make suitable measurements of the states of these different systems.

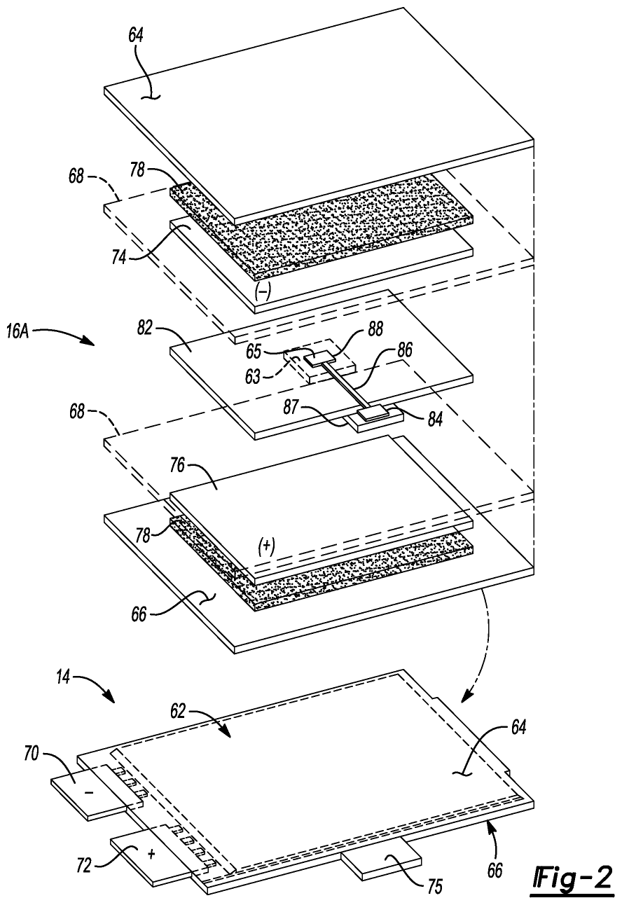

FIG. 2 is a schematic illustration of an example battery cell whose state may be estimated in real time according to the present strategy. As shown in the non-limiting example configuration of FIG. 2, each battery cell 14 may be embodied as a multi-layer construction having an envelope-like pouch 62 with generally flat, rectangular major facing sides 64 and 66. The sides 64 and 66 may be formed of aluminum foil or other suitable material and coated with a polymeric insulating material. The sides 64 and 66 are connected, e.g., via welding or crimping, to enclose an electrolyte solution (shown schematically at 68) that conducts positive lithium ions. Negative (−) and positive (+) tabs 70 and 72 shown at the bottom of FIG. 2 extend from longitudinal edges of the sides 64 and 66, respectively, for making electrical connections with respective negative (−) and positive (+) electrodes, i.e., a lithium metal anode 74 and cathode 76, within an internal volume of the pouch 62. Tab 75 may be coupled to sides 66 to assist in securing the electrolyte solution or to perform other functions.

A series of porous separator sheets 78 are interleaved between the anode 74 and cathode 76 in this exemplary configuration. The anode 74 and cathode 76 are operatively attached to the pouch 62 and placed in electrochemical contact with the electrolyte solution 68 such that ions are transferable therebetween during charging or discharging of the battery cell 14. In an LMB embodiment, the anode is constructed of metallic lithium. In a lithium-ion embodiment, the cathode 76 may be fabricated from material that is capable of supplying lithium ions during a battery charging operation and incorporating lithium ions during a battery discharging operation. The cathode 76 may include, for instance, a lithium metal oxide, phosphate, or silicate. Separator sheets 78 may be constructed of a porous polyolefin membrane, e.g., with a porosity of about 35% to 65%, and a thickness of approximately 25-30 microns. The separator sheets 78 may be modified by the addition of a coating of electrically non-conductive ceramic particles (e.g., silica).

A reference electrode assembly 16A may be used, but it not needed. Instead, the method 100 may rely on modeling of the terminal voltage across both half-cells. When the reference electrode assembly 16A is available, sensing within the scope of the method 100, the reference electrode assembly 16A may be interposed between the anode 74 and cathode 76, and placed in electrochemical contact with the electrolyte solution 68. The reference electrode assembly 16A may function as a third electrode that independently measures a voltage of the anode 74 and cathode 76, and thus the battery cell 14. The reference electrode assembly 16A may be fabricated with a separator sheet 82 that supports an electrical contact 84, an electrical track 86, and an electrical lead 88. The dedicated separator sheet 82 may be fabricated from an electrically-insulating, porous polymeric material, such as polyethylene and/or polypropylene. Separator sheet 82 may be interposed in a face-to-face/non-contacting relationship between parallel faces of the anode and cathode 74 and 76, with the lithium ion-containing electrolyte solution 68 permeating and filling the pores and contacting the surfaces of the sheet 82. An optional jacket separator (not shown) may be disposed across and cover one or both sides of the separator sheet 82, e.g., to help ensure no direct physical contact with the anode and cathode 74 and 76.

In the illustrated example of FIG. 2, a support tab 87 may optionally project transversely from a lateral edge of the elongated separator sheet 82, with the electrical contact 84 deposited on or otherwise affixed to the support tab 87. The electrical track 86 electrically connects the electrical lead 88 to the electrical contact 84. The reference electrode assembly 16A may be fabricated with an intercalation electrode 65 that is deposited on the separator sheet 82 and attached to the electrical lead 88. In the illustrated assembly configuration, electrically non-conductive particles may be deposited to create a very thin alumina layer 63 that is deposited on and covers the intercalation electrode 65 and, consequently, the electrical track 86. This alumina layer 63, which may be on the order of a few atoms thick, helps to stabilize the reference electrode assembly 16A, e.g., for a longer life.

As noted above, regardless of the actual configuration of the battery cells 14, two techniques for roughly estimating SOC of a battery cell 14 include Coulomb counting (i.e., integrating current) and a voltage-based lookup. For Coulomb counting:

$$S O C = S O C ( {t}_{0} ) + \frac{1}{{Q}_{tot}} {\int }_{{t}_{0}}^{{t}_{1}} I ( t ) dt$$

where SOC(t₀) is an initial state of charge value (typically SOC=100% after a full charge) and Qₜₒₜ is the total capacity, also referred to as the intrinsic capacity, of the cell. An equivalent formulation is to define capacity Q(t) as the time integral of current, initialized to zero when the battery is fully charged,

$$Q ( {t}_{1} ) = {\int }_{{t}_{0}}^{{t}_{1}} I ( t ) dt$$

with which, assuming that SOC(t₀)=1, leads to the formula

$$S O C ( t ) = 1 + Q ( t ) / {Q}_{tot} .$$

In these expressions, we are using the convention that discharge current is negative and charging current is positive. Errors in measuring the battery current, I(t), may lead to an accumulation of error in the estimated SOC, i.e., error may accumulate over longer elapsed time periods since a last full charge, and with the larger the number of partial charge events. Uncertainty in battery capacity may lead to error as the capacity degrades over the life of a battery. Estimating the SOC using a voltage lookup technique may rely on the fact that, when the battery 13 is fully rested, the equilibrium voltage/OCV uniquely indicates the SOC. In addition to or in lieu of such approaches, the present method 100 may be used to improve accuracy of BSE methods by applying the high-frequency empirical model 55, and optionally by treating variations in charge distribution through the depth of the anode 74 or cathode 76 via the optional PET model, described in greater detail in U.S. Pat. No. 10,928,457, entitled “Battery State Estimation using High-Frequency Empirical Model with Resolved Time Constant,” issued to the present Assignee on Feb. 23, 2021 and hereby incorporated by reference as if fully set forth herein.

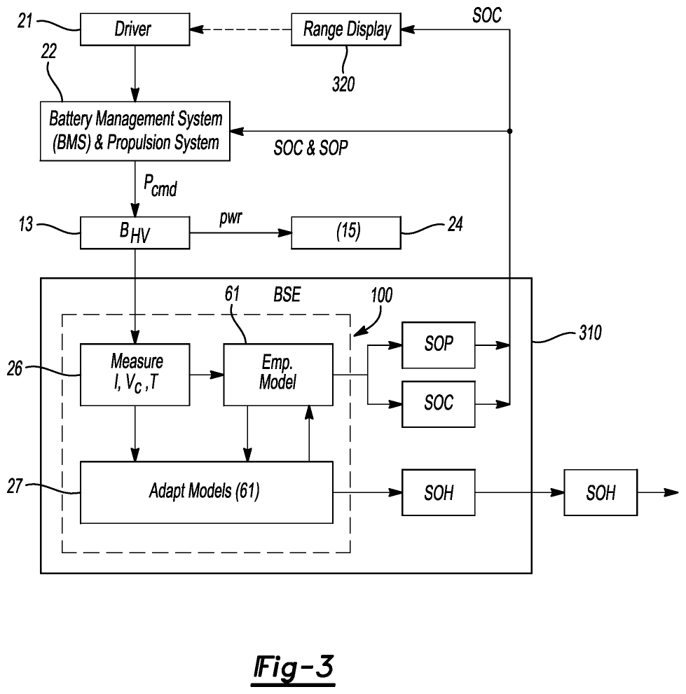

FIG. 3 is a schematic logic flow diagram of the battery and processing system of FIG. 1. A schematic flow diagram of components and control blocks used in the overall BSE process is described with particular reference to FIG. 3. As will be appreciated, knowledge of cell voltage, SOC, battery current flow, and other related states are needed for managing battery functions including predicting failure of LMB cells. For example, improved BSE accuracy enables operation to occur much closer to established battery limits, and thus possibly enable the completion of charge events near the top of an SOC range. The ability to operate at a lower SOC for improving the electric range of the electrical system 12 of FIG. 1 is also possible, with an improved tradeoff between the life and performance of the battery pack 13.

To provide these and other benefits, a BSE logic block 20 may be programmed using logic of the processing system 50 shown in FIG. 1 or another computer device in communication with processing system 50. Control inputs are fed into the BSE logic block 310 from the battery 13, including the periodically measured (actual) cell voltage (arrow V_{C} of FIG. 1) as noted above. In a vehicle embodiment, the driver 21 of the vehicle 10 may impart driver requests that are processed by the processing system 50, e.g., via a battery management system (BMS) and propulsion logic block 22, with requests as acceleration, steering, and braking requests. In response, the processing system 50 outputs a power command (arrow P_{cmd}) to the electrical system 12/battery 13 of FIG. 1 that either charges or discharges the battery 13 depending on an operating mode corresponding to the request. In the illustrated example, for instance, the battery 13 delivers electrical power to a drivetrain 24 of the vehicle 10, such as the electric machine 15 of FIG. 1 when coupled to the road wheels 11 or another driven load. In some embodiments, processing system 50 may be physically integrated with part of the BMS & Propulsion System 22 (FIG. 3).

At the same time, the BSE logic block 310 may predict the total voltage of the battery in battery pack 13 and its SOC according to the present method 100 as detailed below. The estimated state values may be used to make various control decisions, including those based on a state of health (SOH) of the battery 13, SOP, a remaining electric range, etc. An optional display device or range device 320 located within the vehicle 10 may use the estimated state(s) from the BSE logic block 310 to inform the driver 21 of a remaining charge or electric range, akin to how a fuel gauge is employed to indicate an amount of fuel remaining in a fuel tank. SOC and SOP are then fed back into the processing system 50 and used for various control actions, such as to select powertrain operating modes, record diagnostic codes, etc.

Further with respect to the BSE logic block 20 of FIG. 3, various processes and routines may be performed to estimate the voltage between measurements, as well as to estimate SOC and SOP in real-time. For instance, a measurement block 26 with associated hardware measures the current (I), cell voltage (V_{C}), and temperature (T) of the battery of battery pack 13/battery cells 14 at one or more locations. The empirical model 61 (and possibly the optional porous electrode model 58 described in U.S. Pat. No. 10,928,457) is then used to model high-frequency transient voltage effects of the battery cell(s) 14 and battery 13.

The modeled behavior may be used to derive a transient SOP and steady-state SOC, which as noted above are fed back to the processing system 50 and possibly displayed to the driver 21 via the range display 320. An adaptation block 27, e.g., a Kalman filter, may adapt the existing high-frequency empirical model 55 and/or the porous electrode model 58 to more closely match the actual observed behavior of the battery of battery pack 13, with the long-term SOH of the battery 13 possibly generated as another output, e.g., a value between “0” for a depleted battery 13 to “1” for a calibrated/new variant. Adaptation block 27 may use the empirical model 61 in some embodiments.

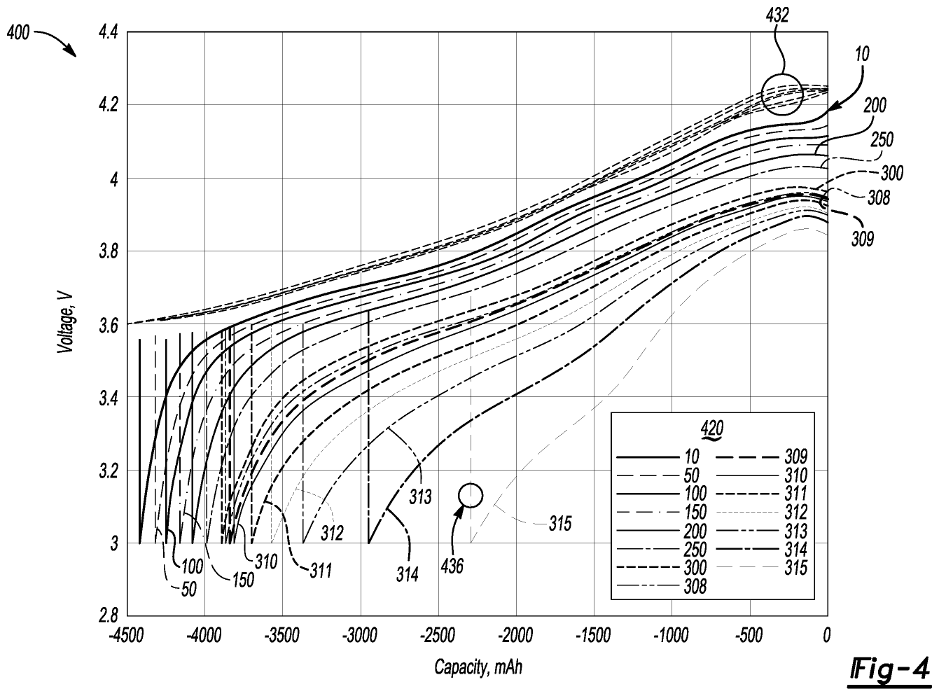

FIG. 4 is a graphical representation 400 of curves of LMB cell voltage (volts) versus battery capacity Q (milliamp-hours) across a plurality of charge-discharge cycles when charging and discharging the LMB cells quickly, during electric vehicle (EV) operation. The experiments that resulted in the curves of FIG. 4 were performed on LMB cells, where the anode is just metallic lithium and the cathode in these embodiments is NMC. The material used in the cathode may vary, however, and FIG. 4 represents just one set of embodiments. Each of these curves is generated during a particular cycle, as noted by the legend 420 in the lower right corner of the graph. The legend 420 shows a relationship between the curves and the total number of charge-discharge cycles (hereinafter sometimes “cycles”). For example, the lowest and rightmost curves on the graph correspond to curves measured at the most recent cycles 315, 314, 313, 312, and 311. For informational purposes and for consistency of definition, one cycle for purposes of graph 400 represents a charging of the battery from completely empty to completely full along with discharging the full battery from its completely full state back to being completely empty. As the battery is discharged, the total capacity used represents the throughput capacity. Cycles in an operational vehicle (which includes a stationary vehicle being discharged) may also be used as points of measurement, including without limitation of resistance, capacity throughput, temperature, voltage, and current. In these practical cases, discussed in detail below, the cycles typically do not fluctuate from completely empty to completely full due at least to the driver's preference to not run out of charge on the roadway.

The horizontal axis of the graph 400 is LMB cell capacity (Q) in milliamperes-hour (mAh). The rightmost value of the horizontal axis is 0 mAh. The vertical axis on the graph represents the corresponding voltage, V, across the anode and cathode of the LMB cell being measured. It is noteworthy that in other configurations a cell group, or a plurality of LMB cells electrically connected in parallel (e.g., connecting the cathodes of each cell in the group to form one effective cathode and connecting the lithium anodes of each cell in the group to form one effective anode). In this other configuration, the voltage measurements may be made across the group—that is, the plurality of cells connected in parallel.

Referring back to the graph 400, it is noted that for each curve that includes a vertical bar such as bar 436, the corresponding curve is measured as a function of capacity Q. That is, at the value of 0 mAh at the rightmost portion of graph 400, the capacity for the LMB cell at the identified cycle (e.g., cycles 10, 50, 100, 150 . . . 310-315), is at a maximum. As the cell is made to discharge quickly (e.g., to approximate an LMB-cell in an equipped, operational EV actively navigating the roadways), the plot of V(t) versus Q(t) moves to the left with the passage of time.

The curves that have the vertical bars (each corresponding to one of the cycles 10, 50, 100 150, 200, 250, 300, 308, 309, 310, 311, 312, 313, 314 and 315) continue to discharge as each respective curve moves to the left. Eventually, the cell discharges, where the complete discharge corresponds to 3 volts on the graph 400. With the age of the LMB cell typically being proportional to the total number of cycles, as the capacity throughput increases, the remaining capacity of the cell decreases. More specifically, the trend on the graph 400 shows that by examining the vertical lines where the cell runs out of charge, it is straightforward to see that the 3 volt mark is reached sooner and sooner with the increasing number of cycles of the LMB cell. For example, the capacity Q of the LMB cell on its 10^{th} cycle reaches approximately 4400 mAh of total charge before it is fully discharged. In contrast, the total capacity Q of the LMB cell on its 315^{th} cycle reaches approximately 2300 mAh prior to its complete discharge. It should be noted that the vertical bars represent the point where the voltage rests after the charge in the LMB cell is depleted. It stands to reason that the voltage is lower when the LMB cell is actively passing current then when the LMB cell is off. The vertical nature of the bar represents the voltage V at a given capacity; it takes time for the voltage to recover after the battery is discharged.

The remaining set of curves, collectively labeled 432 on the graph 400, represents the increasing voltages of the LMB cell during a charging portion of the cycle. As the capacity of the LMB cell increases during the recharge, the voltage likewise increases. During these charging cycles, the direction of time (not graphed) is when the curves 432 move from the left to the right. Again, in the graph 400, the curves 432 are completely discharged prior to recharging. The presence of the vertical bars shows that the LMB cell is progressively discharged at lower and lower capacity throughputs as the cell ages with an increasing number of cycle. Additionally, the source of the problem over the age of the battery may be seen with the loop defined by the discharging curves with their vertical bars at 3 volts getting smaller and smaller as the LMB cell loses the capability to hold charge, until eventually the LMB cell fails.

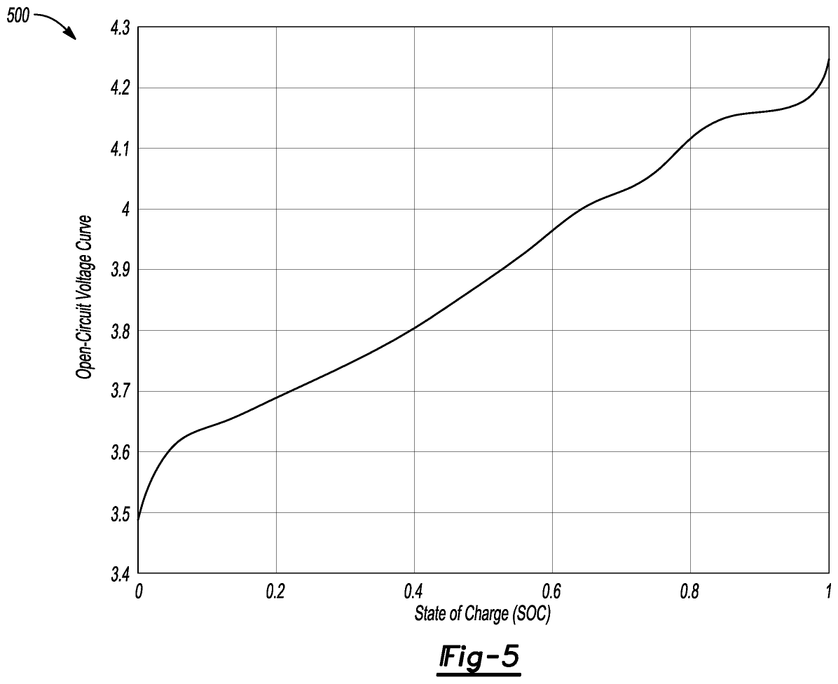

FIG. 5 is a graphical representation 500 of an open-circuit voltage (OCV) in volts as a function of state of charge (SOC) (measured from 0 to 1 or equivalently, 0% to 100%), measured during LMB cell manufacturing with a near-zero charge-discharge rate. While the graphical representation 400 in FIG. 4 shows the LMB cell voltage (which may in other embodiments be a group voltage) when discharging and charging the cell at a cyclical rate corresponding to EV operation, the graphical representation 500 in FIG. 5 shows an open-circuit voltage (OCV) on the horizontal graph as a function of a state of charge (SOC) of the LMB cell.

A battery cell resting at open-circuit, given sufficient time, will settle to an equilibrium voltage referred to as the cell's OCV. Ideally, the OCV of a given battery cell is unique for each SOC, independent of whether the battery cell was charging or discharging just before switching to an open-circuit condition, and also independent of the magnitude of the battery current. OCV increases monotonically as the cell's SOC increases, and thus the relationship between OCV and SOC is invertible. Accordingly, once a given battery cell has rested long enough and its OCV is accurately measured, the SOC may be estimated.

As noted, unlike the voltage measured in graph 400, the OCV curve in FIG. 5 across the LMB cell/group describes near zero-rate operation. Near-zero rate as used in this disclosure describes the OCV plot when charging or discharging the LMB cell very slowly relative to the ordinary operation of LMB cells arranged in a battery pack, the latter which is charged and discharged at a much faster rate. That is, a near-zero rate cycle is one in which the OCV is charging so slowly that current through the LMB cell is effective constant. This OCV voltage is offset by the resistive drop due to the passage of current, sometimes using Ohm's law R=V/I and/or a more sophisticated model accounting for transients, for example, to describe the resistive drop across the LMB cell before normalizing the resistance, as described below.

In other aspects of the disclosure, various techniques may be used to detect the cell resistance, and to normalize and temperature-compensate the resistance for tracking the resistance at a particular state of charge (SOC) and for using the increasing resistance to determine when it will cross a threshold. This information may be used in conjunction with cell charge throughput, temperature, total capacity, and SOC values, described below, to determine anticipated failure onset of one or more identified LMB cells. The advance warning from this procedure gives the EV or other battery-operated device time to alert the owner to attend to the problem, such as by bringing the EV in for service. Referring still to FIG. 5, the OCV value is approximately 3.5 volts when the battery pack is empty at SOC=0. The OCV value rises to about 4.25 volts when the SOC=1 and the LMB cells(s) are fully charged.

To obtain normalized resistance, for example, in some embodiments a minimization function may be employed during the charging portion of the cycle when the EV is recharging, because at least a portion of the charge is in a state of constant current. In other embodiments, the charging cycle may be paused for a brief interval to use the minimization function, because the brief interval represents a fraction of the time it generally takes to charge the vehicle. The charging function takes inputs from the graphical representations 400 and 500 for use in the following example minimization function:

$$Given {R}_{i} ( x ) = ( {V}_{i} ( {x}_{i} ) - O C V ( {x}_{i} ) ) {Q}_{tot , i} / {I}_{i} ( {x}_{i} )$$

$$with {x}_{i} = 1 + {Q}_{i} / {Q}_{tot , i} ;$$

find Q_{tot,j}, ρᵢⱼ to minimize:

$${\int }_{0}^{1} {( {V}_{j} ( {x}_{j} ) - O C V ( {x}_{j} ) - {ρ}_{i j} {R}_{i} ( {x}_{j} ) {I}_{j} ( {x}_{j} ) / {Q}_{tot , j} )}^{2} dx$$

$$with {x}_{j} = 1 + {Q}_{j} / {Q}_{tot , j}$$

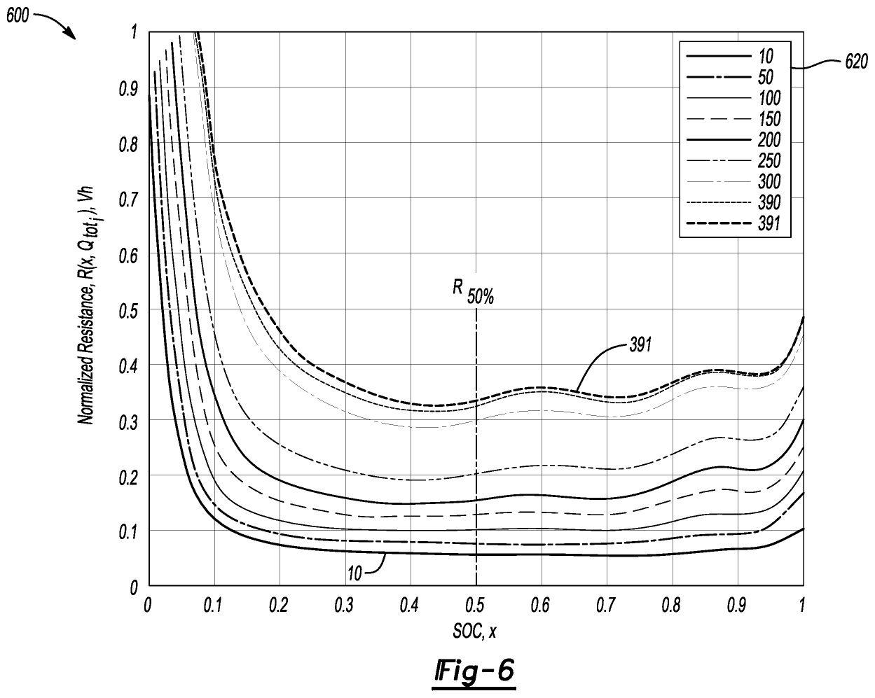

The quantity Qᵢ represents the battery capacity during the i-th cycle, such as obtained in FIG. 4. The quantity Rᵢ(x) represents the resistance of the LMB cell(s) as a function of x, the SOC (FIG. 6). As defined above, xᵢ is a function of the ratio of Qᵢ, the battery capacity during the i-th cycle, to Q_{tot,i}, the total intrinsic battery capacity at the i-th cycle—or more specifically, the SOC at the i-th cycle. Rᵢ (x) may be obtained, for example, based on a measured current flow through the cell(s) and voltage across the cells during the i-th cycle. Vᵢ(xᵢ), measured across the LMB battery terminals, is the i-th cycle voltage as a function of xᵢ. For example, the measurement of Vᵢ is made on the respective current collectors of the anode and cathode (which in turn constitute the metal foils disposed on the outside faces of each electrode) of one or more LMB cells. The quantity OCV(xᵢ) is the open-circuit voltage as a function of xᵢ. The quantity Q_{tot,i} represents the total intrinsic battery capacity at the i-th cycle. Iᵢ (xᵢ), the current through the battery in the i-th cycle at an SOC corresponding to the i-th cycle, may be obtained, for example, by using a current sensor 16 (FIG. 1).

In this example minimization function, ρᵢⱼ represents a scaling factor relating the change in LMB cell resistance from the i-th to the j-th cycle. A value of ρᵢⱼ=1.1 means that the resistance has increased by 10% from the previous i-th cycle to the j-th cycle used by the algorithm as it evaluates changes in the increasing age and resistance of the battery. The quantity Q_{tot,j} represents the total intrinsic battery capacity at the j-th cycle. This is the value of capacity that the EV may obtain when the measurements are made at near zero-rate operation, as opposed to ordinary cycles of the LMB battery pack during operational use of the EV. The value Vⱼ(xⱼ) is analogous to Vᵢ(xᵢ), but at the j-th cycle instead. Likewise, OCV(xⱼ) represents the open-circuit voltage as a function of xⱼ, with xⱼ a counterpart to xᵢ at the j-th cycle. The value Rᵢ(xⱼ) is the i-th cycle resistance as a function of xⱼ.

FIG. 6 is a graphical representation 600 of a normalized resistance R(x, Q_{tot,i}) (also referred to as R^{norm}) in Volt-hours (Vh) versus the quantity SOC (xⱼ) across a plurality of different charge-discharge cycles shown in legend 620. The normalized resistance is also in units of voltage per C-rate or

$$V / ( \frac{I}{{Q}_{t o t}} ) .$$

The normalized resistance may be obtained using various techniques, some of which are described herein, including minimizing the aforementioned function at a constant current. For purposes of this disclosure, LMB operation (unless otherwise clear from the context) may include not just the discharging portion, but also the charging portion, of the cycles. However, in some embodiments the charging portion of the cycle is used to determine the resistance. For example, if the minimization function above is used, it may be used during the charging portion. In other configurations, the empirical model E.M. 55 and/or the BSE logic 52 (FIG. 1) may be used to assist the processing system to make measurements during the charging or discharging portion of LMB operation while taking into account the variable current.

Referring back to FIG. 6, it should be noted that the cycles may be the same or different as those cycles for which curves were generated in the graphical representation 400 of FIG. 4. In this case, the cycles overlap, except that the normalized resistance curves of graph 600 include two additional cycles 390 and 391 to identify the onset of failure. Normalized resistance here is plotted as a function of the SOC, measured from 0 to 1 (or equivalently, from 0% to 100%) as a plurality of curves across a respective plurality of cycles or point in time (although R^{norm} may theoretically take on values greater than one). The cycle 10 corresponds to the lowest curve on this graph 600. In this case, when the SOC at the different cycles crosses a target threshold for each cycle (here SOC=0.5=50%), the increasing value of R^{norm} is indicative of a point, beginning at approximately the 390^{th} cycle, at which an LMB cell will reach an onset of failure. In one aspect of the disclosure, either or both of the increasing values of R^{norm} and the rate of increase of those values, are used to predict cell or group failure. As the number of cycles in FIG. 6 grows, the onset of failure becomes more imminent. For example, the gap between the curves corresponding to cycles 250 and 300 is larger than the gap between the curves for cycles 200 and 250 at the SOC=0.5 point.

It is initially noteworthy that the respective values of fully-developed resistance R^{norm} at the reference SOC point on graph 600 are increasing. Between cycles 10 and 200 for example, the detected normalized resistance values at SOC=50% (R_{50%}) have increased from approximately 0.06 to 0.16 Vh as shown on the vertical axis. In addition, between the R^{norm} at R_{50%} corresponding to cycle 250 versus R^{norm} at R_{50%} corresponding to cycle 300, from the graph it is evident that the increase in R^{norm} between cycle 250 and 300 at SOC=50% (R_{50%}) is 0.1 Vh. However, between the R^{norm} at R_{50%} corresponding to cycle 200 versus R^{norm} at R_{50%} corresponding to cycle 250, the increase in R^{norm} between cycle 200 and 250 at SOC=50% (R_{50%}) is only about 0.04. Furthermore, the difference in R^{norm} at R_{50%} between the earlier cycles 150 and 200 is about 0.02, or half the former value. Thus, from the graph it is clear that, in the above example between 150 and 300 cycles, it is not just that the values of R^{norm} at R_{50%} are increasing, but the rate of increase of R^{norm} is increasing. In these cycles, the rate increase between the example shown is more than double. Advantageously, the processing system 50 including BSE logic 52 may use both the increasing values of R^{norm} and the accelerated rate of the R^{norm} values to predict the onset of failure with greater accuracy and precision.

In sum, in the example of graph 500 and beginning approximately at the R^{norm} value corresponding to 50% at the 200^{th} cycle, it is apparent that the value of R^{norm} is increasing at a faster rate relative to previous cycles. Both the increasing resistance values, and the rate of increase of the resistance, are relevant factors to determining the onset of battery failure. Additionally, the processing system 50 may use these (and other) data to ensure that the R^{norm} values are fully developed, which will increase the accuracy of the prediction technique described below.

Even after the first shown R^{norm} curve at reference numeral 10 (i.e., the 10^{th} cycle), the value of R^{norm} at the SOC=0.5 point is increasing as the battery accumulates cycles. Once the normalized resistance is fully-developed, the processing system may use this and other data to predict LMB cell failure in advance. In one aspect of the disclosure, either or both of the increasing values of R^{norm} and the rate of increase of those values are used to predict cell or group failure. As the number of cycles in FIG. 6 grows and the resistance is fully developed, the onset of failure becomes more imminent. It is also noteworthy that in graph 600, at or near SOC=0.5, the curve corresponding to cycle 391 as a function of increasing SOC is plainly increasing more rapidly than the curve at cycle 200 versus SOC.

In converting resistance to normalized resistance, one relevant concept identified above is “C-rate.” C-rate is current through an LMB cell (or a plurality thereof) divided by total capacity (Qₜₒₜ). For example, for a 5 Ah cell, 1 A of current corresponds to a C-rate of 1/5, while 5 Amps (A) corresponds to a C-rate of 1, 10 A corresponds to a C-rate of 2, and the like. Using normalized resistance, Volts per C-rate, instead of resistance, Volts per Amp, makes an adjustment for how big the battery is. For example, two cells in parallel make a battery with twice the capacity. While the resistance of the pair is halved compared to a single cell, the normalized resistance stays the same. In detail, if the capacity of one cell is Qₜₒₜ, then the capacity of two cells in parallel is 2Qₜₒₜ, while the resistance R for one cell becomes R/2 for the parallel pair. As an example, let V₁ represent the voltage drop across a single resistor for current I₁. For that same total current, the voltage drop across the pair is Vₚₐᵢᵣ=V₁/2. Thus, the resistances are

$${R}_{1} = {V}_{1} / {I}_{1}$$

$$and {R}_{pair} = \frac{{V}_{p a i r}}{{I}_{1}} = \frac{{V}_{1} / 2}{1} = \frac{{R}_{1}}{2} .$$

In contrast, the normalized resistances are:

$${R}_{1}^{n o r m} = \frac{{V}_{1}}{{I}_{1} / {Q}_{tot}} , {R}_{pair}^{norm} = \frac{{V}_{pair}}{\frac{{I}_{1}}{2 {Q}_{tot}}} = \frac{( \frac{{V}_{1}}{2} )}{\frac{{I}_{1}}{2 {Q}_{tot}}} = {R}_{1}^{norm}$$

Accordingly, using R^{norm}, which in turn uses voltage per

$$C - rate , \frac{V}{\frac{I}{{Q}_{tot}}} ,$$

instead of voltage per current, V/I, advantageously removes the influences caused by a difference in LMB cell capacity, and instead the normalized resistance R^{norm} relates directly to the condition of the cell.

Accordingly, in various embodiments, the processing system maintains a running estimate of the cell's capacity Qₜₒₜ (which declines over time). When the processing system performs a resistance measurement, instead of dividing voltage by current to get resistance in ohms, the processing system in these embodiments divides voltage by C-rate to obtain normalized resistance. Using other techniques to obtain a normalized resistance may also be possible without departing from the spirit and scope of the present disclosure. For example, in various embodiments, the processing system may measure resistance using R=V/I and then convert it to normalized resistance using R^{norm}=RQₜₒₜ.

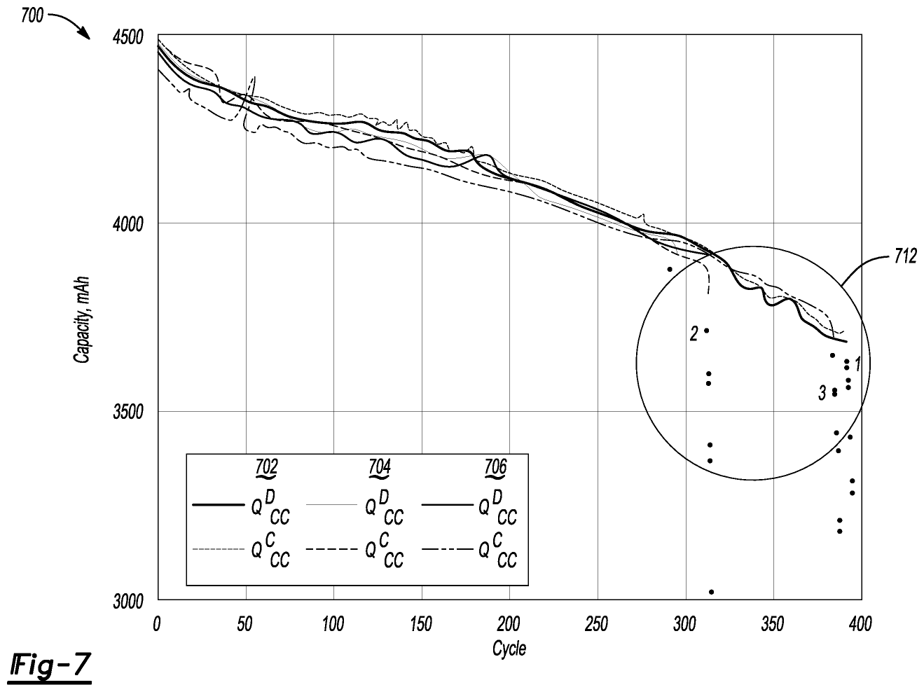

FIG. 7 is a graphical representation 700 of three example LMB cells 702, 704, and 706, respectively, reaching catastrophic capacity failure between 300 and 400 charge-discharge cycles. The values of constant current discharge capacity Q^{D}_{CC} and constant current charge capacity Q^{C}_{CC} (in milliamp-hours (mAh)) for each cell are shown as curves in graph 700 at increasing charge-discharge cycles. The hardware elements involved in this determination may in practice include the battery back in which the LMB cells or cell groups are encased, the processing system, the voltage and current sensors as well as one or more temperature sensors for identifying cell temperature and compensating the normalized resistance values accordingly, as discussed in greater detail below. Referring to graph 700, data for three cells are shown. The first cell 702 has a weight per capacity of 2.2 g/Ah. The second cell 704 has a weight per capacity of 2.4 g/Ah, and the third cell has a weight per capacity of 2.5 g/Ah. Each of cells 702, 704, and 706 is associated with two curves on the graph 700. One curve represents the discharge capacity at constant current, while the other curve represents the charging capacity at constant current. The graph 700 shows the three cells 702, 704 and 706 aging as a function of the total number of cycles over time. The original cells, when new, started at values close to a capacity Q_{TOT} of 4500 mAh, as shown near the vertical axis on the upper right portion of graph 700. As the number of cycles on the horizontal axis began to accumulate over time, the respective values of capacities Q^{D}_{CC} Q^{C}_{CC}, but for a few minor and isolated artifacts, also reduce in Q_{TOT} with the increase in cycles and do so almost in lock step with the other cells 704 and 706.

The circular region identified in 712 shows catastrophic capacity failure, beginning with cell 704. The number “2” positioned within region 712 proximate the sudden capacity drop shows the drastic failure in capacity of cell 704 at or about 308 cycles, since the respective curves are shown as a near-vertical set of dots descending quickly from about 3850 mAh to the minimum on the graph 700 of 3000 mAh. Subsequently at about seventy cycles later, cell 706 fails as shown by the number “3” in region 712. The sudden capacity drop is reflected by both Q^{D}_{CC} Q^{C}_{CC} values flowing quickly downward in a similar manner. At the 390^{th} cycle, the failure of cell 702 is visually apparent by viewing the corresponding Q^{D}_{CC} Q^{C}_{CC} as those curves flow down to the minimum on the graph 700, and in a similar manner.

The cells 702, 704 and 706 as tested above show the actual failure of the cells. Various aspects of the disclosure, including the detection of normalized resistance, conversion of the normalized resistance to a temperature-compensated resistance as it crosses an SOC threshold, and detection of a minimum charge difference or a maximum trend line based on a number of successive resistance, capacity and temperature measurements (described below) are demonstrated that enable the processing system to observe these failures in advance and that provide a prognostic alert (e.g., a red “service battery” light or a stream of data sent wirelessly to service center or other location over a network system for subscribers of the vehicle's owner).

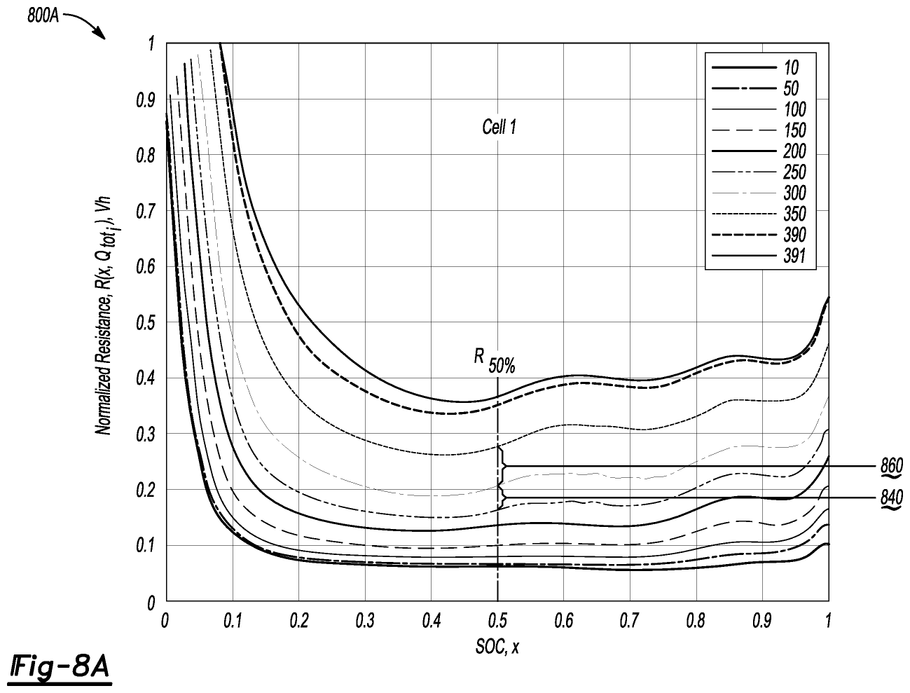

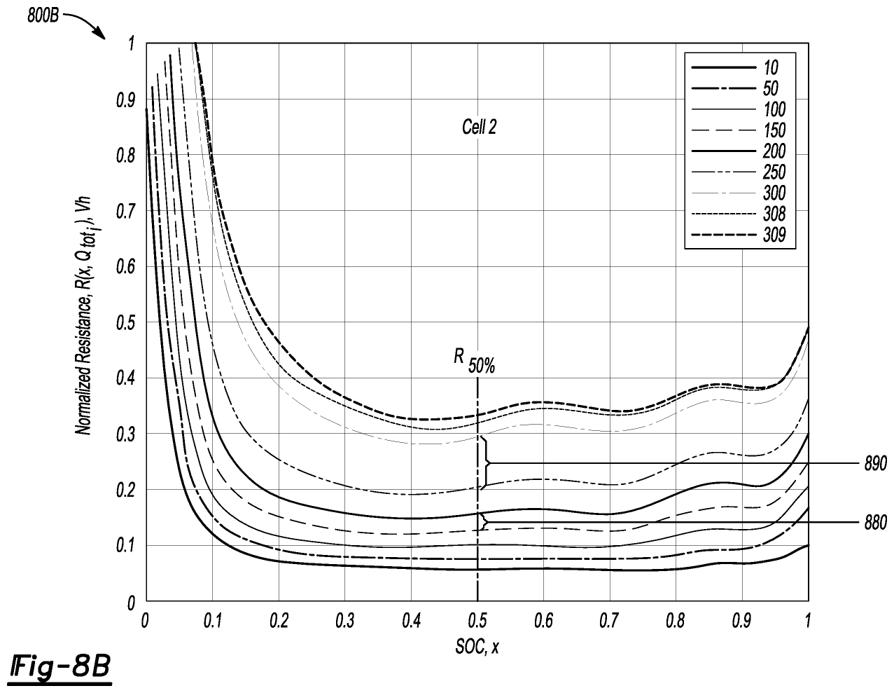

FIG. 8A is a graphical representation 800A of failure onset of the cell 1 (702) in FIG. 7, and more specifically, curves showing, at different charge-discharge cycles, values of normalized resistance R^{norm} (in Volt-hours (V-h)) as a function of SOC x and Q_{TOT}, versus SOC x. In various implementations of the battery failure detection scheme, a threshold SOC value may be preselected to trigger the recording of a normalized resistance (R^{norm}) value at an SOC value of 50%, or equivalently a value of R^{norm} where the SOC crosses a target value of 0.5. While the examples in the previous charts show the preselected value to be 50% of the SOC, it should be understood that in actual operation of an EV or other transport structure equipped with an LMB battery pack, the owner may commonly begin to recharge the vehicle at a non-zero value of capacity. In view of this propensity of drivers of EVs, it is likely that many individuals will recharge their batteries when the SOC is already just below or even above 50%. Accordingly, in various embodiments, the target value of SOC when recording of the normalized resistance is triggered may be another value, such as 0.8, designed to help ensure that in the course of operation of the vehicle will discharge to an SOC below the target SOC and later recharge to an SOC above the target SOC. Accordingly, this value may vary depending on factors like the size of the battery, the observed behavioral propensities of EV drivers, and other factors. Further, in selecting the appropriate SOC value, the extremes (e.g., close to 0, such or close to 1) should be avoided as threshold points, because resistance naturally changes at the approaching extremes (i.e., near 0% and 100% SOC).

Like in previous embodiments, R^{norm} increases for increasing cycles. Referring still to FIG. 8A, the line 840 identifies a lower vertical bracket that corresponds to the crossing points of normalized resistance at the preselected R_{50%} value. As shown in the bracket of line 840, the normalized resistance R^{norm} at SOC=0.5 (R_{50%}) has increased between 250 and 300 cycles by about 0.3 Vh. However, as shown in the bracket of line 860, the normalized resistance R^{norm} at SOC=0.5 (R_{50%}) has increased between 300 and 350 cycles by about 0.7 Vh. Thus, the vertical brackets demonstrate both the increasing values of R^{norm} and the increasing rate of those values may be indicative of impending LMB cell failure.

In various aspects of the disclosure, both the presence of increasing values of normalized resistance and the rate of increase may be factors that the processing system will take into account in making predictions about future failures. In the transition from the curve R^{norm} at 250 cycles to the subsequent crossing at 300 cycles, the values of R^{norm} in a given cycle are increasing as they cross the 0.5 SOC point. In the ensuing transition from 300 to 350 cycles as shown by the upper bracket leading via a line to reference numeral 360, there appears to be not just the pattern of increasing resistance seen previously with respect to the crossing at cycle 250, but also a not insubstantial increase in the rate of R^{norm} growth between the transition of 300 and 350 cycles identified by reference numeral 860. This detected behavior of R^{norm} may be used by the processing system to actively begin its prediction modalities, described below.

Regardless of whether the rate of resistance growth is increasing (which may be one factor in assessing impending catastrophic failure), the trend of increasing values of normalized resistance across the preselected SOC point continues. The processing system may use these detected increased values of normalized resistance at each of the crossing cycles and store the data in memory for use in predicting an estimated capacity to failure.

FIG. 8B is a graphical representation 800B of failure onset of the second cell 704 in FIG. 7, and more specifically, curves showing, at different charge-discharge cycles values of normalized resistance R R^{norm} (as a function of SOC X and different Q_{TOT} values) versus SOC X. As previously shown, cell 704 was the first cell to fail. Like in FIG. 8A, FIG. 8B shows R^{norm} versus SOC, using R_{50%} as the crossing point for detecting the normalized values and beginning the process of predicting failure onset at the appropriate point (using additional values described herein). Other values of SOC may be used.

Referring to the reference numeral 880, the corresponding vertical bracket shows that at the crossing point of R^{norm} at R_{50%}, the normalized resistance at 150 cycles appears to be fairly steady and demonstrates a modest but noticeable increase in R^{norm} proportional to the vertical width of the corresponding bracket. Thereafter, reference for comparison is made between two subsequent SOC=0.5 crossings in FIG. 8B as shown by the bracket corresponding to reference numeral 890, the values of normalized resistance R^{norm} at R_{50%} as detected at 250 and 300 cycles. The difference in these R^{norm} as shown in the upper vertical bracket at reference numeral 890 appear to triple the difference in corresponding R^{norm} values at the lower vertical bracket at reference numeral 880. Thus, referring still to reference numeral 890 at the ensuing crossings of R^{norm} at R_{50%}, the increased values of normalized resistance between cycle 250 and cycle 300 are even more conspicuous. Like the trend in FIG. 8A, both the R^{norm} values and the rate of change in the values are increasing during certain ranges of the cycles. At subsequent cycles, the increasing values appear to at least stay its course. The processing system may determine the resistance and may make further measurements of capacity throughput and temperature, etc., to accurately predict failure onset.

For both the graphical representations 800A and 800B, the various points (R^{norm}) and others are recorded in memory so that the trend may be evaluated as the onset of failure gets closer. In addition to the voltage and current sensors of the processing system transmitting their information at the different crossing values, one or more temperature sensors may be used at or proximate the cells to record their temperatures. Also, in both graphical representations 800A and 800B, absent a defective cell, the data appears to suggest that a potentially large number of charge-recharge cycles will pass prior to the increasing values to become more pronounced and more reliably crossing the relevant SOC threshold with a consistent or increasing rate of increased R^{norm} value.

It is also noteworthy that the embodiments described above, and the equations enumerated in this disclosure, may apply with equal force to groups of LMB cells, and to one or more serial strings of groups arranged in one or more battery packs. To add clarity and to avoid unduly obscuring the concepts of the disclosure, the operation and failure at the cell and group level has been examined first. However, the principles of battery failure and corresponding predictions and alerts are applicable at arbitrary levels of LMB cell/group/battery complexity. In addition, the principles herein also extend to cathodes having different materials, to different electrolytes, separators, and generally to LMB cells with different architectures and different geometrical characteristics. For example, the LMB cells may be pouch-like or cylindrical, or they may be embodied in another form. The number of cell groups and the number of serial strings of cell groups, if more than one, may benefit from the concepts herein and fall within the scope of the disclosure.

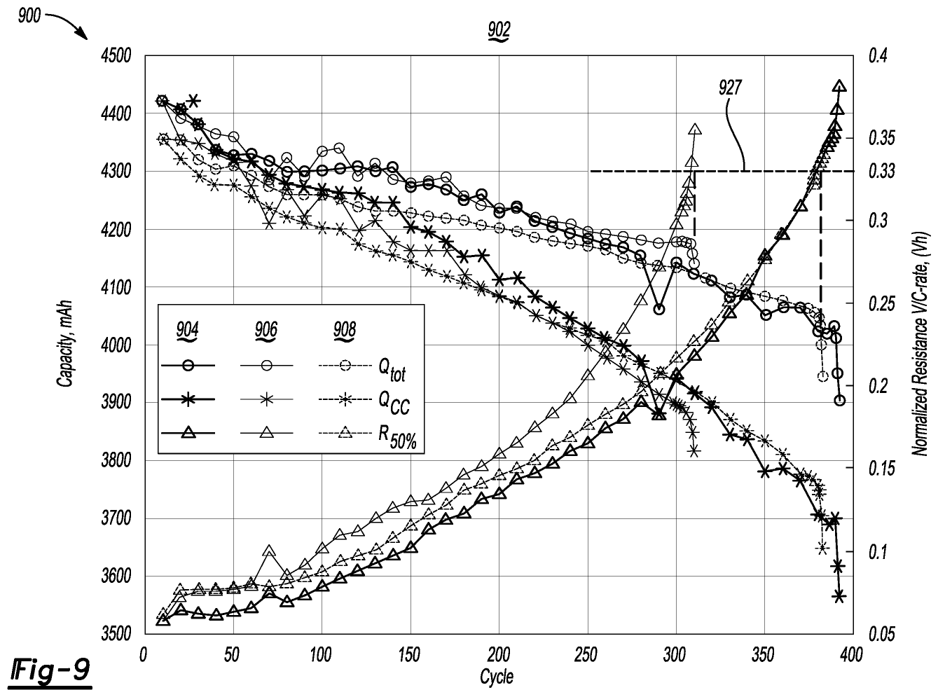

FIG. 9 is a graphical representation 900 of LMB cell capacity in milliamp-hours (mAh) and normalized resistance (V/C-rate or Vh) 902 of three LMB cells 904, 906 and 908. The data plotted includes, for each respective LMB cell 904, 906, and 908, total capacity (Q_{TOT}) and constant current capacity (Q_{CC}) in milliamp-hours (mAh), with the normalized resistance (V/C-rate) in volt-hours (Vh) again for example purposes at R50% (i.e., the value of R^{norm} at SOC=0.5 or 50%). The horizontal axis shows the increasing cycles. Like in the previous examples, a different SOC crossing value may be selected in various embodiments to obtain potentially more effective detection and prediction procedures when taking into account average user or driver behavior in charging their devices/EVs, and by avoiding a threshold that corresponds to an extreme value close to 0 or 1.

Referring now to FIG. 9, the horizontal axis of the graph 900 represents the increasing number of cycles in the previous graphs, and the capacity ranging from 3500 mAh to 4500 mAh is shown on the left vertical portion of the graph 900. On the right vertical portion of the graph is a suitably scaled R^{norm} axis, with R^{norm} measured in the usual V/C-rate or Vh values. For these three cells 904, 906 and 908, the legend identifies that the circle-covered curves display Q_{TOT}, or the total capacity for each cell. As expected, Q_{TOT} tends to decline over the time, or here, the number of cycles. The asterisk-covered curves represent the constant current capacity Q_{CC} of the three respective cells. The triangle-covered curves constitute the normalized resistance of each cell taken here at the example R_{50%} value, although in other embodiments, a different SOC threshold value may be used as discussed at length above. As before, each of the three cells 904, 906 and 908 may be differentiated as shown in the legend, with the underlying curves corresponding to cell 904 in bold, the underlying curves corresponding to cell 906 in regular solid-line style, and the underlying curves corresponding to cell 908 in dashed line style.

One interesting phenomenon in comparing these cells is that, as shown by the dashed straight line 927 in the upper right portion of the graph 900, the capacity failure coincides very closely with the point where the normalized resistance at SOC=50% crosses the 330 mV/C-rate point (i.e., R^{norm}=0.33). That is to say, even though capacity failure may occur at different cycles (here, somewhere between 300 and 400 cycles), the value of R^{norm} at capacity failure is approximately the same. That is, R^{norm} is 330 mV/C-rate for two of the cells 906 and 908 where the triangular covered curves intersect line 927, and for cell 904 where the triangular covered curve crosses the 350V/C-rate of R^{norm} at SOC=50%. FIG. 9 also shows the the curves showing the constant current capacity and the total capacity Q_{TOT} quickly fall off at failure. Nonetheless, by monitoring the trend of resistance, the point of failure of the cells may be predicted ahead of time. Further, as noted, acceleration in the rate of increase is another indicator of imminent capacity failure.

### Detecting Resistance Growth During LMB Operation

Various embodiments may be used to detect increasing values of resistance in LMB cells and/or battery packs of EVs, hybrid vehicles, and other mobile transport devices in operation. In vehicles, discharges do not usually involve constant current running through the LMB cell/pack. The overvoltage, V—OCV, that develops in response to a varying current exhibits transient effects. For example, a jump in current from one constant level to another higher level gives an immediate jump in voltage, associated with a short-term resistance and followed by a more gradual increase to a final, fully-developed resistance. In the case of a rapidly varying current, the overvoltage is influenced by a spectrum of resistances called the impedance spectrum of the battery. However, as noted and unlike the discharge portion, large portions of the charge protocol run at or near constant current, in which case the fully-developed resistance of the battery dominates. The algorithm used to measure the values leading to the graphs on FIGS. 4-6 may be one of several techniques used to estimate the fully-developed resistance during each charge. This includes estimating resistance for constant-current cycling, including (1) measuring LMB cell voltage (V) as a function of capacity throughput (mAh) across the relative age or number of cycles of the LMB cells (FIG. 4), (2) determining a curve corresponding to OCV at near zero rate operation (FIG. 5), and (3) using a minimization or other function, a suitable equivalent circuit, an empirical model, or another processing technique to determine, for a plurality of cycles, a value of normalized resistance that depends on the C-rate. In the third case, the values of normalized resistance crossing the SOC threshold may be detected at a plurality of points, each point corresponding to a different cycle or instant in time. At the same point, the processing system may use the sensors to determine the capacity throughput (Q^{thru}) (e.g., using current and voltage values, etc.), and the LMB cell temperature (T) at each of the same points. Here, the capacity throughput is the time integral of the absolute value of current:

Q^{thru}=∫|I|dt

which increases monotonically throughout the life of the battery as it charges or discharges. In a vehicle application, it often happens that the battery is not fully discharged before recharging commences and likewise charging may stop before the battery reaches its full state. Because of this, different cycles in a plurality of cycles contribute different amounts to the capacity throughput, with a smaller cycle expected to cause less growth in resistance than a cycle with a large throughput capacity.

The measurements at different throughput points or increasing cycles of R^{norm} of the LMB cell or cell group at the target SOC value show that the fully-developed values of R^{norm} are increasing, thereby reducing constant-current discharge capacity that the battery delivers before reaching a set voltage floor. Even as resistance is growing, the total intrinsic capacity, Q^{TOT} may be decreasing, which also results in a reduction in the constant-current discharge capacity.

The measurements of the different values of the normalized resistance can be stored in memory along with capacity throughput Q^{thru} and temperature T at each point as part of a plurality of increasing cycles or in some embodiments, instances in time. As described below, the normalized resistance values can be properly compensated or modified as needed based on the deviation of the actual measured temperature at which R^{norm} was taken from some reference temperature. Thereafter, when a least-squares or similar algorithm is employed as discussed below, the compensated temperature value R^{comp} can be assigned a lower weight based on the extent of its deviation from the reference temperature.

To measure resistance during operation of a vehicle, even when current is varying, one may fit the parameters of an equivalent circuit model (ECM) using K-EQ 54 (FIG. 1), for example, to minimize the error between the model's prediction of the voltage and the measured voltage. Given a time-history of current, an ECM predicts a corresponding voltage response. A voltage prediction of a typical ECM may include a sum of an open-circuit voltage, a hysteresis voltage, an ohmic resistor, and one or more resistor-capacitor pairs. Fitting may be formulated as a recursive least-squares process, such as described in U.S. Pat. No. 7,373,264, issued on May 13, 2008 to the present assignee, and incorporated by reference as if entirely set forth herein. In other embodiments, fitting may be implemented using various forms of Kalman filters. A related modeling approach is taught in U.S. Pat. No. 10,928,457 (described above) wherein the ohmic resistor and resistor-capacitor pairs are replaced by a set of resistances that each multiply a different basis function, each basis function depending on the present current or one or more lagged currents, each lagged current being a low pass filter with a prescribed time constant. For the purpose of the present disclosure, the resistance used in the prognostic algorithm may be just the instantaneous ohmic resistance, or the sum of each of the resistances, also referred to as the fully-developed resistance, or some weighted combination of the above-identified set of resistances.

The accuracy with which the resistances of a model may be estimated also depends on the frequency content of the applied current. If the current is constant or nearly constant, then just the fully-developed resistance is accurately identifiable. However, since an IR voltage drop is constant for constant current I and resistance R, the fully-developed resistance may be difficult to distinguish from a steady voltage offset, which may be due to an offset error in estimating the cell state of charge. For this reason, US Pat. Pub. No. 2021/0336462, published Oct. 28, 2021 on behalf of the present assignee and incorporated by reference as if fully set forth herein, discloses that during episodes of nominally constant-current, the estimation of resistance is improved by superimposing an oscillating current. Such variation in current may consist of a short interruption in current or a train of such interruptions, or some other variation in current that has a broader frequency content compared to constant current. This approach is especially applicable during charging episodes, where current is often held constant or slowly varying over long periods. A single pulse gives a strong identification of ohmic resistance observable in the immediate change in voltage at the instant current changes, while the longer term evolution of voltage during and after the pulse reveals longer-term resistances. An in-vehicle test of impedance based on current pulses is closely related to the laboratory technique referred to as Galvanostatic Intermittent Titration Technique (GITT). If sinusoids of various frequencies are applied instead, the process is related to the laboratory technique referred to as Electrochemical Impedance Spectroscopy (EIS).

For the purpose of the present disclosure, a full spectrum of impedance may not be needed, so the length of pulses or the selection of sinusoids may be tailored to extract a meaningful prognostic signal while minimizing the adverse effect on the operation of the battery. In particular, in many cases, a single current interrupt pulse lasting a few seconds to several minutes will have a minimal effect on the total charge time of a battery pack. When fast-charging a vehicle, solely short interruptions may be tolerated, but this may already suffice to measure instantaneous and short-term resistances.

While the previous paragraphs cast the problem of measuring resistances in terms of measuring the response of voltage to current, the problem may equivalently be cast as the response of current to voltage, which produces measures of admittance, the reciprocal of impedance. As a spectrum of admittances may be converted to equivalent resistances, the present disclosure may in some embodiments be reformulated in this way. This approach is related to the laboratory technique referred to as Potentiostatic Intermittent Titration Technique (PITT).

Referring now to the SOC detection point, as noted previously, not every charge starts below 50% SOC. As such, in various embodiments, another target SOC value may be used for detecting the crossing threshold. For example, R_{80%} in lieu of R_{50%} may be used as the detection point. In various embodiments, to increase the accuracy of the overall measurement scheme, the processing system may instead determine the mean normalized resistance over a specified range of SOC:

$${R}_{a v g} = \frac{1}{{x}_{2} - {x}_{1}} {\int }_{{x}_{1}}^{{x}_{2}} R ( x ) d x$$

where x₁ and x₂ represent the endpoints of the specified range of SOC.

In still other embodiments, the processing system may obtain short-term resistances during the charging portion of the cycle instead of an otherwise operational EV or hybrid vehicle using an LMB battery pack. This is true where, as here, at least portions of the charge cycle operate at constant current. During these periods, the processing system may take the various measurements of capacity throughput, voltages, currents, and temperature, for storage in memory using the various sensors 16 incorporated into the processing system 50 (FIG. 1).

In still further embodiments during charging, short-term resistances may be measured via a current interrupt interval or via other current oscillations. The current interrupt interval may be, for example from 10 seconds to 30 seconds, or it may be a similar value that has a negligible effect on the total charge time of the battery pack. For example, in some embodiments, the processing system may use the measured data to obtain a best fit line of V=OCV(x)+V₀+R_{Ω}I+R_{τ}u, wherein τ\dot{u}=I−u; with u being current filtered with a time constant τ, \dot{u} being the time derivative of u and which best fit may be used by the processing system to provide estimates of ohmic resistance, R_{Ω}, and the short-term resistance R_{τ} (For example, τ=1s may be appropriate for a 10s current interrupt.) Ohmic resistance R_{Ω} may be generally defined as the apparent internal resistance of the battery pack 13 and the resistance of the various electrical conductors used in the battery pack's construction. R_{Ω} tends to manifest as an instaneous cell voltage response to changes in battery current. More generally, u may be a state vector column encoding the time history of current at various time scales, in which case R_{τ} is a row vector of associated resistances. The state vector u of a dynamical system is a list of state values that gives the information needed to predict how the system will evolve in time in response to known inputs. If the model of a battery is of a physicochemical type, its state vector might describe the distribution of local SOC throughout the battery. A further discussion of related models is set forth in U.S. Pat. No. 10,928,457. As an example, the battery may include a plurality of cell groups, with each cell group having a plurality of LMB cells. The groups may be then strung together in serial fashion. The sensors 16 (FIG. 1) may output measured signals indicative of actual parameters of the battery pack 13, including actual voltage, current, and temperature values of each battery cell. The processing system 50, in response to the measured signals, may estimate the full state vector of the battery using an open-circuit voltage (OCV) and an empirical model E.M. 55 (FIG. 1) of higher-frequency voltage transients. The processing system 50 may thereafter control an operating state of the electrical system in real-time responsive to the estimated state, including a predicted voltage of the battery. For instance, the operating state may be a charging or discharging operation of the battery.

The empirical model 55 may include low-pass and/or band-pass filters and a high-pass filter, each with a different time-constant collectively spread over a predetermined time-constant range, with three or more low-pass and/or band-pass filters used in an optional embodiment. The current sensor signal is the input of each filter. The output of each filter branches through one or more basis functions whose respective outputs are then multiplied by a respective calibrated resistance value to generate the above-noted higher-frequency voltage transients. At least one basis function may be a non-linear basis function. The processing system 50 may sum the voltage transients with the estimated OCV to derive a predicted voltage as part of the estimated state. At a given time instant, the state of the empirical model is an array of numbers containing the set of filter outputs and the OCV. The state may also include the list of resistance values. The processing system 50 may periodically adjust the state of the empirical model based on a difference between the predicted and actual voltages. Also, the controller may derive an SOC of the battery using the estimated state, and also may adjust the empirical model in real-time for improved model accuracy, e.g., by periodically adjusting the respective calibrated resistances based on the SOC and/or the temperature.

In an open-circuit state, the OCV has a non-linear curve relating the voltage to the state of charge SOC. Such a state exists when the battery in the battery pack 13 (FIG. 1) has rested at open-circuit, i.e., with no battery current (I) flowing into the battery cells 14 in the battery pack 13 for a duration sufficient for reaching the equilibrium state. OCV is thus an important indication of the actual energy remaining in the battery pack 13.

High-frequency and low-frequency voltage losses are then considered as behavior effects once the OCV has been determined. A low-frequency loss may be due to the hysteresis offset and labeled “ [symbol] Hyst(θ)” with −1≤ [symbol] ≤1. An ordinary differential equation may be used to determine [symbol] , e.g., depending on the sign of the battery current (I), as will be appreciated, with hysteresis modeled for both charging and discharging modes of operation. Hysteresis and an optional porous electrode model, as described in U.S. Pat. No. 10,928,457, may collectively capture low-frequency behavioral effects of the battery cell 14 of FIG. 1. High-frequency phenomena, such as those caused by the diffusion of lithium intercalating into solid particles, the diffusion of lithium ions in the electrolyte solution 68 of FIG. 2, double-layer capacitance, etc., are handled separately by the high-frequency empirical model, E.M. 55, in FIG. 1.

In various embodiments, an overpotential RC circuit model may be used to roughly characterize high-frequency transient voltage behavior. In the context of battery technology, overpotential is the potential difference (voltage) between an electrochemical reaction's thermodynamically determined reduction potential and the potential at which the redox event is experimentally observed. The overpotential is related to the efficiency of an LMB cell. An RC circuit model is representable as follows:

$$V = {R}_{O} I + {v}_{1} + … + {v}_{n} ,$$

$${C}_{i} {\dot{v}}_{i} = I - \frac{{v}_{i}}{{R}_{i}} , I = 1 , … , n .$$

Here, a high-frequency resistor R_{O}, possibly with non-linear behavior, is in series with multiple resistor (Rᵢ)-capacitor (Cᵢ) pairs, e.g., R₁C₁ . . . R_{N}C_{N}, to collectively represent additional losses that may further affect the open-circuit voltage. Example approaches for implementing RC pairs in such a manner are disclosed in U.S. patent application Ser. No. 14/171,334, published as US 2015/0219726A1 to Lenz et al. and incorporated by reference in its entirety.

In other embodiments, the BSE algorithm may already provide regressed estimates of resistances at several time scales for both charge and discharge, even when current is not constant. For example, reference is made to U.S. Pat. No. 10,928,457 in which regressed resistance estimates during both charge and discharge are measured using a controller, BSE, and one or more empirical models. In another example, the processing system may determine calibrated resistances Rᵢⱼ, which are functions of the SOC and temperature. These values may be tuned during initial testing and stored in the memory M (FIG. 1) of the processing system 50 such that they are accessible to the BSE logic 52. In various embodiments, the resistance values may be regressed in real-time.

In various embodiments, other resistance values may be taken into account. There is also resistance associated with each component of the battery current (I), i.e., a temperature-dependent charge-transfer resistance describing resistance to a transfer of charge into a particle, as will be appreciated, and a temperature-dependent effective pore resistance that is the resistance to moving lithium ions down pores of the electrode, i.e., a function of the electrolyte material 68, pore size, etc. The processing system 50 may use the empirical model to account for high frequency effects, thereby increasing the accuracy of the resistance measurements. As noted, in various embodiments, a current interrupt during charging will help ensure that the BSE's estimates are accurate.

In other embodiments, resistance may be detected by using current oscillations, as disclosed in U.S. Pat. App. Pub. No. US 2021/0336462, described above. For example, the processing system may use an application-specific equivalent circuit model E.M. 55 to accurately estimate and regress OCV, ohmic resistance (R_{Ω}), and impedance of the battery pack, with SOC being a representative battery states that may be estimated from such battery parameters. The BSE 52 (FIG. 1) may be configured to regress these and other battery parameters for use in normalized resistance prediction. These techniques may include using an extended Kalman filter or other Kalman filter formulation. Selectively requesting the injection of the current oscillations into the constant baseline current may include requesting a constant charging current, via the controller, from an offboard charging station as the constant baseline current, and wherein controlling powerflow to or from the battery pack includes charging the battery pack using the final current. Alternatively, selectively requesting the injection of the current oscillations into the constant baseline current includes selectively controlling an ON/OFF state of an electrical load connected to the battery pack while receiving or delivering a constant baseline current to thereby create the current oscillations. Controlling the powerflow to or from the battery pack in this instance may include discharging the battery pack to the electrical load.

In various further embodiments, selectively requesting the injection of the current oscillations into the constant baseline current may include selectively requesting, from an offboard charging station, a series of constant charging currents each having a different frequency content to thereby create the current oscillations, and wherein controlling the powerflow to or from the battery pack using the estimated battery state includes charging the battery pack using the final current, or communicating a charging request from the controller to an offboard smart charger. Such a smart charger may be configured to detect a requirement of the battery pack for the final current, and that is configured to transmit the final current to the battery pack as a charging current. The battery parameter may include an ohmic resistance, an impedance, and/or an open-circuit voltage of the battery pack in various embodiments. These parameters may in turn be used to estimate accurate values of ohmic resistance, impedance, and OCV of the LMB cell(s) and/or the battery pack 13, from which the processing system may calculate accurate values of the normalized resistance.

In still other embodiments for predicting growth of the normalized resistance, the processing system 50 and BSE logic 52 of the present disclosure may selectively combine weighted combinations of the above measures for predicting normalized resistance. For example, the most reliable measures may be implemented and compared with other measures, with a greater weight given to more reliable measures and a lower weight to less reliable ones, to obtain mean curves of normalized resistance across cycles of the battery pack 13.

In still further aspects of the disclosure, the processing system 50 may use the measurements of normalized resistance at the relevant SOC value to predict the capacity to failure of one or more identified failing LMB cells, or of the entire battery pack, depending on the physical configuration of the cells. Aspects of these predictions are described in greater detail, below.

### Predicting Capacity to Failure of Identified Failing LMB Cells.

For a given LMB cell design, the manufacturer of an EV may establish in the laboratory the onset resistance (R*) where rapid capacity loss begins. The slope m*=dR/Q^{thru} at the onset R* may also be recorded, where Q^{thru} is amp-hour throughput.

In another aspect of the disclosure, the value of R* established prior to vehicle assembly may be compensated for temperature. Laboratory tests at different temperatures may be temperature-compensated using different techniques. In various embodiments, to determine a temperature compensated normalized resistance R^{comp}, an Arrhenius relationship of the following form may be used:

$${R}_{T}^{*} \approx {R}_{{T}_{0}}^{*} exp [ a \cdot ( \frac{1}{{T}_{0}} - \frac{1}{T} ) ]$$

where R_{T}* is the onset resistance at temperature T (in ° K), T₀ is a reference temperature (typically 25° C.=298.15° K), and a is a fitting parameter. More generally, one may empirically fit parameters of a function ƒ(T) to approximate R_{T}*≈R_{T}_{₀}*ƒ(T), where

$$f ( T ) = exp [ a \cdot ( \frac{1}{{T}_{0}} - \frac{1}{T} ) ] .$$

Solving this relationship for the equivalent resistance at reference temperature T₀, one has

$${R}_{{T}_{0}}^{*} = \frac{{R}_{T}^{*}}{exp [ a \cdot ( \frac{1}{{T}_{0}} - \frac{1}{T} ) ]} = {R}_{T}^{*} exp [ a \cdot ( \frac{1}{T} - \frac{1}{{T}_{0}} ) ]$$

The above expression in this example is the one that may in practice be implemented: it takes a resistance measured at temperature T and produces an equivalent resistance at the selected reference temperature T₀. It is noteworthy that the inversion of the Arrhenius relation just happens to take a simple form because

$$\frac{1}{{e}^{x}} = {e}^{- x} .$$

In other embodiments, where another compensation function is more effective based on the LMB cell design or other factors, then the temperature-compensation algorithm may implement more general relations, including but not limited to the following:

$${R}_{T}^{*} = {R}_{{T}_{0}}^{*} f ( T ) , {R}_{{T}_{0}}^{*} = \frac{{R}_{T}^{*}}{f ( T )} .$$

In still other embodiments, in addition to the Arrhenius form, the temperature-compensation calculation may use linear or quadratic forms, ƒ(T)=1+a(T−T₀) or ƒ(T)=1+a₁(T−T₀)+a₂(T−T₀)², or one of a variety of suitable empirical functional forms.

Regardless of the specific temperature-compensation employed, once a fleet of vehicles is in the field, the quantities R_{25° C.}*and m* may be revised to reflect real-world experience. Thus, the processing system 50 including the BSE logic 52 (FIG. 1) may adjust for temperature compensation using more accurate temperature values and/or onset trend lines that may be directly measured by a temperature sensor 16. Using one of these temperature-compensation procedures may advantageously increase the accuracy of the detected resistance and the prediction of failure onset. In short, the value of R^{comp} corresponding to R_{T}* represents the temperature-compensated normalized resistance in which the onset of LMB cell/battery failure occurs.

In various embodiments, e.g., in an operational EV (where “operational” includes both charging and driving (discharging) portions of a cycle), at times t₁, t₂, . . . , tₙ, the processing system may obtain respective normalized resistance values R^{norm} of R₁, R₂, . . . , Rₙ as measured for an LMB cell using one of the methods described herein, or another technique. Thereupon, the processing system may obtain, using voltage, current and temperature sensors, the sets of Q^{thru}, Tᵢ), i=1, . . . , n, which are the cumulative amp-hour throughput and temperature of the cell at times t₁, . . . , tₙ. The processing system may also compute and store in memory the temperature compensated resistance values. The temperature compensated resistances may thereupon be generated from the Rᵢ values, where \tilde{R}ᵢ=Rᵢ/ƒ(T) where the “tilde” refers to a temperature-compensated normalized resistance, and where the quantities \tilde{R}ᵢ and R^{comp} are interchangeable.

The processing system may then use the trend line based on \tilde{R} vs Q^{thru} to predict Q*, where Q* represents the value of Q^{thru} where \tilde{R} will cross R* (i.e., the onset resistance). At instant tₙ, Q*−Qₙ^{thru} is the predicted amp-hours to failure. In one embodiment, the trend line is computed considering just the points within X amp-hours of the present. (X is a tunable parameter of the algorithm and may be changed to correspond to a desired recency.) Points farther back in history are no longer relevant.

In addition, points with temperature T too far from the reference temperature may be ignored or down-weighted in fitting the trend line. This helps ensure that the relied upon values of temperature-compensated resistance are accurate. The slope of the trend line approximates the derivative dR/dQ^{thru}. A slope approaching m* is another prognostic for capacity failure.

It should be understood that, while the above embodiments correspond in some cases to one or a few cells, the principles of this disclosure are not so limited. That is, the detecting and predicting procedures may be performed in one embodiment for each cell group (cells connected in parallel) in a battery pack. The cell predicted to fail first may determine the failure point for the pack.

### Providing Prognostic Alert

As discussed above in connection with various embodiments, the predicted amp-hours to failure, Q*−Q^{thru}, may be converted to an estimate of miles to failure based on the history of the vehicle's miles/Ah or on an engineering estimate of miles/Ah. When miles to failure falls below a prespecified threshold, the vehicle issues a warning recommending battery service. An alert may instead be triggered if the rate of increase of resistance (i.e., the slope of the resistance trend line) exceeds a threshold, or some combination of the two signals is monitored and an alert issues accordingly using both measures (amp-hours to failure and slope of trend line).

The vehicle information record may identify which cell or cells are approaching failure, which may help a service technician perform diagnosis and repair. In some embodiments, the alert may be sent over a wireless network or proprietary network associated with the model of the EV. The alert may include information such as the amp-hours to failure or miles to failure.

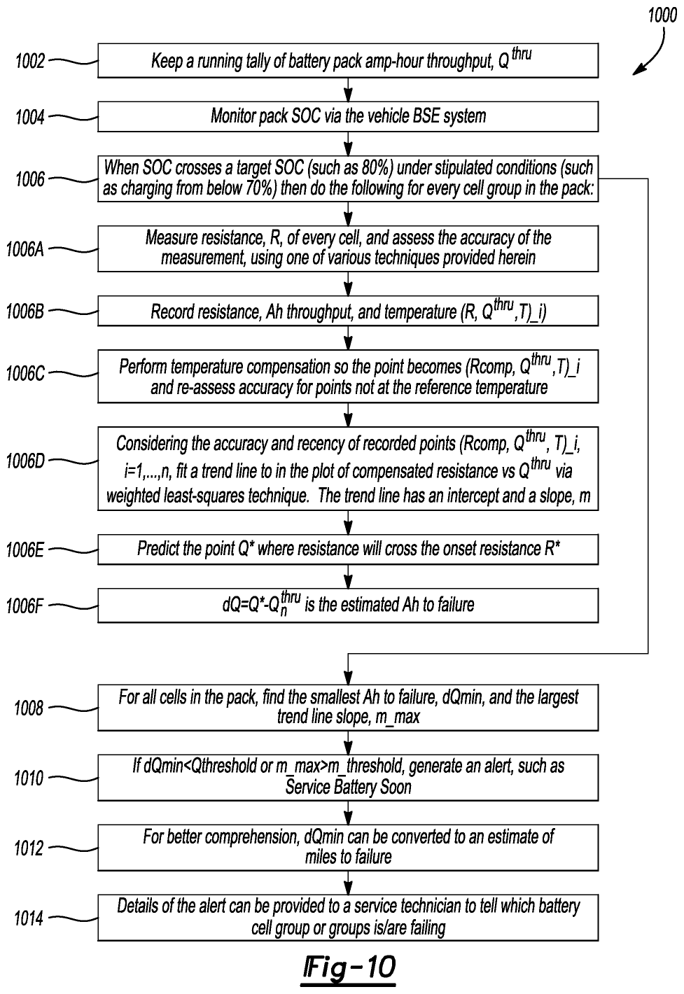

FIG. 10 is a flow diagram 1000 illustrating an exemplary method for predicting a remaining battery capacity or mileage to anticipated failure in an EV and for providing a prognostic alert. The steps in the method of FIG. 10 may be performed by the processing system 50 including the BSE logic 52, E.M. 55, equivalent circuit model (K-EQ) 54, and the one or more processors P, as well as the various sensors 16 for measuring cell characteristics including voltage, temperature T, current I, and the like. The memory M may be used to store preexisting data performed prior to vehicle assembly and sale. The memory M may also be used to store the measured values and plot the data logically over time or cycle number. The memory M may also include executable code for execution by the one or more processors P, and/or for use by the computer-implemented method. As noted, the processing system 50 may be part of the battery management system, and may use the same processors in some embodiments.

Referring initially to step 1002, the processing system 50, during vehicle operation and recharging portions, keeps a running tally of the amp-hour throughput Q^{thru}. The amp-hour throughput Q^{thru} may include the lifetime accumulated amount of charge and discharge used by the battery pack 13. At step 1004, the processing system 50 regularly monitors the SOC of the battery pack via the BSE logic 52. In some embodiments, the BSE logic may be implemented as one or more hardware elements, or a combination of hardware, middleware, firmware, and software. The BSE logic 52 may therefore include executable code, or dedicated hardware processing circuitry such as digital signal processors, ASICs, Boolean logic circuits, and the like. In some arrangements, the BSE logic 52 may be executed on the one or more processors P.

Thereupon, at step 1006, when the SOC crosses a target SOC at stipulated conditions, such as at target SOC=80% with the driver charging from below 70%, then the processing system 50 is programmed to perform a series of steps 1006A-F. At step 1006A, the processing system measures the normalized resistance, R^{norm} of every LMB cell at the target SOC and assesses the accuracy of the measurement using one of the techniques described herein. Values may be modified, or truncated for certain measurement points, as needed to accurately reflect the normalized resistance. At step 1006B, the processing system stores the resistance, capacity throughput Q^{thru} (e.g., in Ah, or the total amount of capacity charged and discharged), and temperature measurements, in memory for a point i in time or a specified cycle i as (R^{norm}, Q^{thru}, T)ᵢ(in some embodiments depending on the measurement technique employed, the measurement point may be a cycle or a specified portion therein). Temperature and capacity throughput Q^{thru} may be obtained using voltage and current sensors, measured resistance values, and temperature sensors. At 1006C, the processing temperature performs temperature compensation to convert each of the stored R^{norm} values to corresponding R^{comp} values so that each point i is now associated with corresponding values of (R^{norm}, Q^{thru} T)ᵢ.

At step 1006D, upon taking into account the relative accuracy and recency of the recorded points (by weighting values that deviate from an expected result, deleting values, or truncating older values as described above), the processing system, for the potentially-modified and remaining points in (R^{norm}, Q^{thru} T)ᵢ, may fit a trend line to the plot of compensated resistance versus Q^{thru} using a weighted least squares technique or another exemplary numerical technique. The trend line includes an intercept, such as a value of R_{comp}, and a slope denoted m. At step 1006E, the processing system 50 may predict the point Q*, which represents the value of Q^{thru} where R^{comp} (also referred to as \tilde{R}) will cross R* (i.e., the onset resistance). At step 1006F, the processing system 50 may thereafter compute the value of dQ=Q*−Qₙ^{thru} as the predicted amp-hours to failure and Qₙ^{thru} represents the capacity throughput corresponding to the point n, wherein i=1, 2, 3 . . . n.

Referring back to step 1006, the steps 1006A-F have been performed for each cell group in the battery pack 13. Control next passes from step 1006 to step 1008. In this exemplary embodiment, the estimated capacity to failure of each of the cell groups in the battery pack has been determined. Thereupon at step 1008, the processing system is configured to identify, for each cells (or cell group) in the pack, the smallest capacity (e.g., in Ah) to failure, dQₘᵢₙ, and the largest trend line slope, m_max. At step 1010, in the event dQₘᵢₙ<Q_{threshold} with Q_{threshold} being a specified value, then the processing system generates an alert. The alert may be a “service battery soon” light or icon, for example.

At step 1012, the processing system may convert dQₘᵢₙ to an estimated distance to failure. This embodiment provides additional useful information to a driver. At step 1014, details of the alert may be provided to a service technician, including the cell group(s) that are failing. The information may include the anticipated capacity to failure and/or the predicted distance (miles/kilometers) to failure, along with other data that may be useable by service technicians. In other embodiments, the driver may simply see the alert and drive the vehicle to a service center.

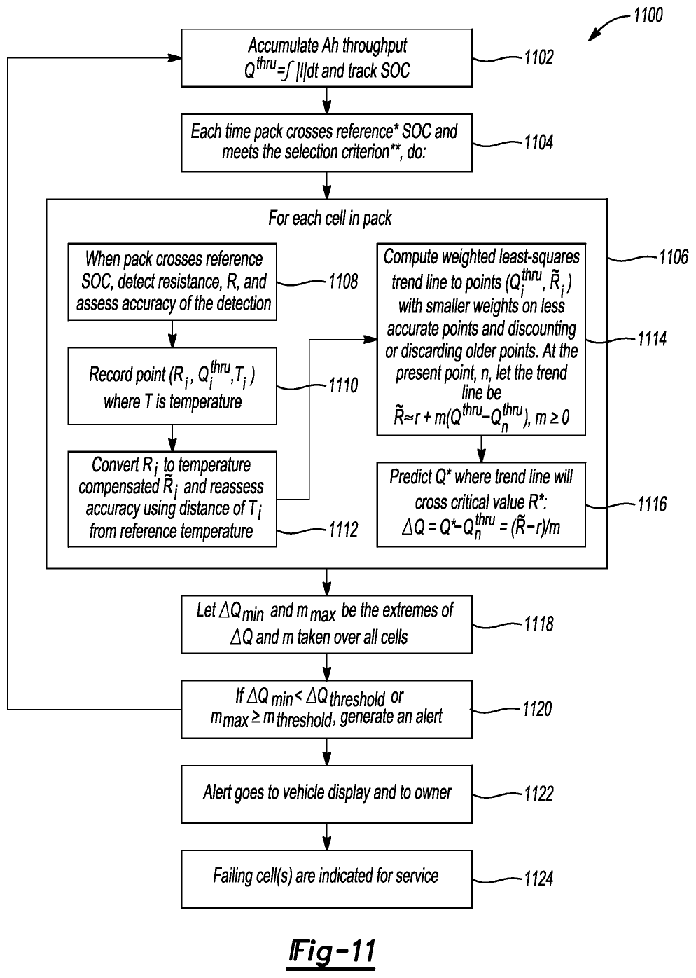

FIG. 11 is a flow diagram 1100 illustrating another exemplary method for predicting battery failure in advance in a vehicle using a normalized resistance and for providing a prognostic alert to the driver. Like in FIG. 10, the steps of FIG. 11 may be performed by the processing system 50 (FIG. 1) including the BSE logic 52, E.M. 55, equivalent circuit 54, and the one or more processors P, as well as the various sensors 16 for measuring cell characteristics including voltage, temperature T, current I, and the like. The memory M may be used to store preexisting data performed prior to vehicle assembly and sale. The memory M may also be used to store the measured values and plot the data logically over time or cycle number. The memory M may also include executable code for execution by the one or more processors P, and/or for use by the computer-implemented method 100. As noted, the processing system 50 may be part of the battery management system and may use the same processors in some embodiments.

In the embodiment of FIG. 11, steps 1102 and 1104 are applicable to the battery pack. At step 1102, the processing system may accumulate the capacity throughput (e.g., in Ah) and track the values of SOC. The capacity throughput may be obtained for example, using current sensors 16 along with the equation:

Q=∫|I|dt

where |I| is the absolute value of current running serially through the battery pack. In some embodiments where more than one serial connection of cell groups is present, then the additional current(s) may be measured, and the total charge capacity throughput determined. At step 1104, each time the battery pack crosses a reference SOC and meets certain selection criteria, then a series of steps may be undertaken, in this embodiment for each cell in the battery pack. Concerning the reference or preselected SOC, it is noteworthy that resistance values vary quickly for SOCs to near either extreme at 0% or 100%, (see, e.g., FIG. 6). It is consequently advisable to select a reference SOC that is away from these end points. Due at least in part to driver tendencies to ensure that the drivers' EVs have adequate charge, many vehicles are only occasionally discharged to a low SOC. As such, a reference SOC around 80% or thereabout may provide the processing system with more opportunities to make meaningful measurements and thus more opportunities to exercise the prognostics for battery failure. Setting the target SOC at about 80% is likewise not so high as to enter the region where the normalized resistance changes at each cycle at high SOC values. Nevertheless, the changing resistance values at both SOC extremes should be measured to ensure an effective target SOC is selected.

Concerning the selection criteria in step 1104, one such example is the embodiment where the battery pack is charging from an initial SOC=70% and the reference SOC=80%. Depending on whether this example criterion is such that prognostic measurements should be avoided, the resolution may depend on which method is used for detecting normalized resistance and making predictions relevant to battery prognostics. The designer may be able to ascertain the conditions under which a given condition is accurate enough for inclusion in the process, or should be omitted.

Referring to block 1106, as noted, the disclosed embodiment in steps 1108, 1110, 1112, 1114, and 1116 is performed for each LMB cell in the battery pack. At step 1108, when the battery pack crosses the reference SOC, the processing system may detect the resistance R, normalize it to R^{norm}, and assess the accuracy of the detection as described above. At each point i in which a measurement is made, the normalized resistance R^{norm}ᵢ along with the ith capacity throughput Qᵢ^{thru} and Temperature Tᵢ at step 1110 may be stored in memory as points (R^{norm}ᵢ, Qᵢ^{thru}, Tᵢ). At step 1112, R^{norm}ᵢ is converted into a temperature-compensated resistance \tilde{R} (also referred to herein as R^{comp}). The accuracy of \tilde{R} is reassessed such that points that deviate from the reference temperature may be weighted less and temperatures Tᵢ that are close to the reference temperature may be weighted more heavily, and certain values are deleted based on their lack of recency and/or their excessive temperature deviations.

Thereupon, at step 1114, the processing system may compute a weighted least-squares trend line to points (Q^{thru}, \tilde{R}ᵢ) with smaller weights on less accurate points and discounting or discarding older points. At the present point n, the trend line may take the form \tilde{R}ᵢ=Q*−Qₙ^{thru}=m(Q^{thru}−Qₙ) m≥0. At step 1116, the processing system may predict the value of Q* where the trend line will ultimately cross a critical value R*—namely, ΔQ=Q*−Qₙ^{thru}=(\tilde{R}−r)/m. Control then passes out of block 1106 to step 1118, which in this embodiment returns back to the battery pack level. At step 1118, the processing system calculates ΔQₘᵢₙ and mₘₐₓ to be the extreme values of ΔQ and m, respectively, taken over each cell. At step 1120, if ΔQₘᵢₙ<ΔQ_{threshold} or if mₘₐₓ≥m_{threshold}, the processing system is configured to generate an alert. The alert at step 1122 may be displayed on the vehicle display and to the owner via a proprietary wireless network. Further, at step 1124, the failing cell(s) are identified for service.

LMBs offer the attributes of high energy density and low cost, both highly desirable in the context of EVs and other mobile forms of transportation. Otherwise, when owners are caught by surprise with sudden capacity failure, the vehicle may suddenly become inoperable, which is an unacceptable outcome. By providing a prognostic warning as described in the principles herein, the owner is given an opportunity to service the vehicle before outright failure.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims. Moreover, this disclosure expressly includes combinations and sub-combinations of the elements and features presented above and below.

What is claimed is:

1. An electrical system, comprising:
a battery pack including a plurality of Lithium Metal Battery (LMB) cells, each LMB cell of the plurality having a respective terminal pair; and
a processing system coupled to the respective terminal pairs and configured to:
detect, during LMB cell operation, increasing values of a normalized resistance across at least one of the terminal pairs corresponding to an identified at least one of the LMB cells;
predict, based on the increasing values of normalized resistance, a throughput capacity corresponding to an anticipated failure of the identified at least one of the LMB cells; and
provide a prognostic alert based on the prediction.

2. The electrical system of claim 1, wherein the anticipated failure of the identified at least one of the LMB cells corresponds to the increasing values of normalized resistance crossing a threshold at a preselected state of charge (SOC).

3. The electrical system of claim 1, wherein the processing system is configured to detect the normalized resistance (R^{norm}) such that:
the R^{norm}=R₀Qₜₒₜ is in units of voltage (V)/C-rate;
the C-rate is current divided by total capacity (current/Qₜₒₜ);
the Qₜₒₜ represents a total capacity of the at least one of the LMB cells; and
the R₀ represents a resistance across the at least one of the LMB cells.

4. The electrical system of claim 3, wherein the processing system further comprises:
a voltage sensor configured to measure the voltage (V) across the at least one of the terminal pairs; and
a current sensor configured to measure the current (I) through the at least one of the LMB cells.

5. The electrical system of claim 3, wherein the processing system is further configured to periodically estimate the total capacity Qₜₒₜ of the at least one of the LMB cells and to obtain the values of normalized resistance (R^{norm}) using the estimated Qₜₒₜ values and one or both of the measured voltage (V) or the measured current (I).

6. The electrical system of claim 1, wherein the processing system is configured to:
convert the values of normalized resistance (R^{norm}) to temperature-compensated resistance (R^{comp}) and to assess accuracies of values of R^{comp} based at least in part on a deviation of temperatures from a reference temperature; and
predict the anticipated failure by monitoring a trend line fit to the values of the temperature compensated resistance (R^{comp}) and a throughput capacity Q^{thru} over a plurality of measurements.

7. The electrical system of claim 1, wherein the processing system is configured to identify an accelerated rate of increase of the values of the normalized resistance as an indicator of imminent capacity failure of the identified at least one of the LMB cells.

8. A vehicle, comprising:
a vehicle body;
a battery pack arranged within the vehicle body and including a plurality of Lithium Metal Battery (LMB) cells, each LMB cell having a cathode and a lithium anode that together constitute a terminal pair of the respective LMB cell; and
a processing system coupled to the respective terminals pairs and configured to:
detect, over a period of time, progressively increasing values of a normalized resistance between terminal pairs corresponding to at least one identified LMB cell of the plurality;
predict a remaining throughput capacity prior to imminent failure of the at least one identified LMB cell wherein the increasing values cross a threshold at a reference state of charge (SOC); and
provide a prognostic alert based on the prediction.

9. The vehicle of claim 8, wherein the processing system comprises:
voltage and current sensors for respectively measuring voltage (V) across the terminal pairs and current flow (I) through the LMB cells;
battery state estimation (BSE) logic to monitor cell capacities, Qₜₒₜ_{ⱼ}, wherein j comprises an index over the plurality of LMB cells, and the SOC of the battery pack; and
a memory coupled to the voltage and current sensors for storing data.

10. The vehicle of claim 9, wherein:
the processing system detects the progressively increasing values at least in part by:
reading, from the memory, stored values of an open-circuit voltage (OCV) of the at least one identified LMB cell, the OCV measured at different SOC values during a near-zero rate cycle prior to vehicle operation to obtain initial resistance values that depend on a C-rate;
measuring, over the period of time, a plurality of first sets of V values, each V value in each first set representing a voltage measured at a throughput capacity (Q^{thru}); and
detecting, at the reference SOC, and based in part on the initial resistance values and a difference between the stored OCV values and the measured V values in each set, the normalized resistance.

11. The vehicle of claim 9, wherein the processing system is further configured to:
measure, over the time period, a plurality of values of the normalized resistance values (R^{norm}ᵢ), throughput capacity (Qᵢ^{thru}) and temperature (Tᵢ) of the at least one identified LMB cell when the SOC crosses a target value;
determine a first accuracy of each of the R^{norm} measurements including modifying or deleting unreliable measurements;
store the R^{norm}ᵢ, Qᵢ^{thru} and Tᵢ values in the memory as an i-th measurement point in a sequence of such points;
perform temperature compensation for selected R^{norm}ᵢ values to obtain a temperature-compensated resistance (R^{comp}ᵢ) for storing in the memory with the corresponding Q^{thru} and T values; and
determine a second accuracy of R^{comp}ᵢ for each new point comprising R^{comp}ᵢ, Q^{thru}ᵢ and Tᵢ values including assigning a different weight to one or more of the R^{comp} values based on a measured temperature deviating from a reference temperature and deleting the R^{comp}ᵢ values that are based on measurements that exceed a threshold age.

12. The vehicle of claim 11, wherein the processing system is configured to:
fit a weighted-least squares trend line or curve in a plot of R^{comp}ᵢ versus Q^{thru}ᵢ over the period of time, the trend line or curve having an intercept and a slope m*, the trend line or curve based at least in part on assigning higher weights to more accurate R^{comp} measurements and lower weights to less accurate R^{comp} measurements; and
predict a value (Q*) of a battery capacity wherein R^{comp} crosses an onset resistance.

13. The vehicle of claim 12, wherein to predict a remaining capacity of the at least one identified LMB cell, the processing system is configured to determine, for each of the plurality of LMB cells, a difference between a value (Q*) of the battery throughput capacity wherein the trend line of R^{comp} crosses the onset resistance, and a present battery throughput capacity (Q^{thru}).

14. The vehicle of claim 12, wherein the processing system is further configured to predict a remaining throughput capacity of the at least one identified LMB cell using a slope of the trend line or curve.

15. The vehicle of claim 8, wherein the processing system is further configured to determine a predicted distance to failure for inclusion within the prognostic alert.

16. The vehicle of claim 8, wherein the processing system is further configured to convey the prognostic alert to one or both of an output display in the vehicle or to a remote location via a wireless network.

17. The vehicle of claim 8, wherein the prognostic alert further includes an indication of the at least one identified LMB cell corresponding to the imminent failure.

18. A vehicle, comprising:
a vehicle body;
a battery pack arranged within the vehicle body and including a plurality of LMB cells connected in series, each LMB cell having a cathode and a lithium anode that together constitute a pair of terminals of the at least one LMB cell; and
a processing system coupled to the plurality of LMB cells and configured to:
measure, over time, a current through the plurality of LMB cells connected in series to establish a throughput capacity (Q^{thru}) of the battery pack;
track a state of charge (SOC) of the battery pack over time;
when the throughput capacity at an ith measurement (Q^{thru}ᵢ) crosses a reference SOC, detect a normalized resistance (R^{norm}) across the terminals of the at least one LMB cell and assess a detection accuracy;
store values of R^{norm}ᵢ, Q^{thru}ᵢ, and a measured temperature (Tᵢ) at the ith measurement in a memory;
convert R^{norm}ᵢ to a temperature-compensated resistance R^{comp}ᵢ and reassess an accuracy of values of R^{comp}ᵢ based on deviations from a reference temperature;
fit a trend line to points (Q^{thru}ᵢ, R^{comp}ᵢ);
predict a capacity (Q*) at which the trend line of an R^{comp}ᵢ will cross an onset resistance;
estimate a capacity to failure (Q*−Q^{thru}) of the at least one LMB cell based on the trend line; and
provide a prognostic alert on a vehicle display.

19. The vehicle of claim 18, wherein the temperature-compensated resistance (R^{comp}ᵢ) is obtained using an Arrhenius relationship.

20. The vehicle of claim 18, wherein the processing system is further configured to:
predict the capacity to failure by determining when the trend line or curve of the compensated resistance R^{comp}ᵢ will cross a specified threshold; and
provide the prognostic alert when a minimum capacity change (ΔQₘᵢₙ) falls below a first threshold or a maximum slope of the trend line crosses a second threshold,
wherein for each of the plurality of LMB cells, ΔQ=Q*−Q^{thru} and ΔQₘᵢₙ is a smallest value of the plurality of LMB cells.
